(19) United States
(12) Patent Application Publication
(10) Pub. No.: US 2026/0169388 A1
(43) Pub. Date: Jun. 18, 2026

(54) SUBSTRATE PROCESSING METHOD AND SUBSTRATE PROCESSING APPARATUS

(71) Applicant: Tokyo Electron Limited, Tokyo (JP)

(72) Inventors: Congque DINH, Koshi City, Kumamoto (JP); Seiji NAGAHARA, Tokyo (JP); Makoto MURAMATSU, Koshi City, Kumamoto (JP)

(73) Assignee: Tokyo Electron Limited, Tokyo (JP)

(21) Appl. No.: 19/122,357

(22) PCT Filed: Oct. 10, 2023
(86) PCT No.: PCT/JP2023/036703

§ 371 Date: Apr. 18, 2025

(30) Foreign Application Priority Data
Oct. 20, 2022 (JP) 2022-168555
Jun. 28, 2023 (JP) 2023-106451

(51) Int. Cl. G03F 7/32; G03F 7/16; G03F 7/20

(52) U.S. Cl. CPC G03F 7/32; G03F 7/168; G03F 7/2002

(57) ABSTRACT

A substrate processing method includes developing, using a polar developing material and a non-polar developing material, a substrate on which a film of a negative type metal-containing resist is formed and on which an exposure processing and a heating processing after the exposure processing are performed.

### TECHNICAL FIELD

The various aspects and embodiments described herein pertain generally to a substrate processing method and a substrate processing apparatus.

### BACKGROUND

Patent Document 1 describes a method of forming a developed pattern-formed layer including an organometallic oxide/hydroxide network by developing an organometallic patterning layer exposed to radiation.

### PRIOR ART DOCUMENT

Patent Document 1: Japanese Patent Laid-open Publication No. 2022-526031

### DISCLOSURE OF THE INVENTION

### Problems to be Solved by the Invention

Exemplary embodiments provide a technique enabling an increase of exposure sensitivity of a film of a metal-containing resist. In addition, the exemplary embodiments also provide a technique enabling reduction of scum remaining on a substrate when forming a pattern of the metal-containing resist.

### Means for Solving the Problems

In an exemplary embodiment, a substrate processing method includes developing, using a polar developing material and a non-polar developing material, a substrate on which a film of a negative type metal-containing resist is formed and on which an exposure processing and a heating processing after the exposure processing are performed.

### Effect of the Invention

According to the exemplary embodiments, it is possible to increase exposure sensitivity of the film of the metal-containing resist. Further, according to the exemplary embodiment, it is also possible to reduce scum remaining on the substrate when forming the pattern of the metal-containing resist.

### BRIEF DESCRIPTION OF THE DRAWINGS

FIG. 1 is an explanatory diagram schematically illustrating an internal configuration of a wafer processing apparatus as a substrate processing apparatus according to an exemplary embodiment.

FIG. 2 is a diagram schematically illustrating an internal configuration of a front side of a wet processing section.

FIG. 3 is a diagram schematically illustrating an internal configuration of a rear side of the wet processing section.

FIG. 4 is a diagram schematically illustrating a cross section of a delivery block of the wafer processing apparatus of FIG. 1.

FIG. 5 is a flowchart showing main processes in Example 1 of a processing sequence.

FIG. 6 is a partially enlarged cross sectional view for describing an intermediate exposed region, schematically illustrating a metal-containing resist film after being subjected to exposure.

FIG. 7 presents a graph showing comparison of thicknesses of a metal-containing resist film after being subjected to development in two separate cases where the development is performed first using a non-polar developing material and then using a polar developing material as in Example 1 of the processing sequence and where the development is performed using only the non-polar developing material.

FIG. 8 is a flowchart showing main processes of Modification example 1 of Example 1 of the processing sequence.

FIG. 9 presents a graph showing comparison of thicknesses of a metal-containing resist film after being subjected to development in two separate cases where the development is performed as in Modification Example 1 of Example 1 of the processing sequence and where only non-polar development is performed.

FIG. 10 is a diagram showing a relationship between critical dimension (CD) of a pattern of a metal-containing resist film after being subjected to development and an exposure dose.

FIG. 11 is a diagram showing a relationship between CD of a pattern of a metal-containing resist film after being subjected to development and roughness of the pattern.

FIG. 12 is a diagram showing a relationship between CD of a pattern of a metal-containing resist film after being subjected to development and a defect ratio.

FIG. 13 is a diagram illustrating an example configuration of a developing module configured to perform both non-polar development and polar development.

FIG. 14 is a flowchart showing main processes of Example 2 of the processing sequence.

FIG. 15 is a flowchart showing main processes of Modification Example 1 of Example 2 of the processing sequence.

FIG. 16 is a flowchart showing main processes of Modification Example 2 of Example 2 of the processing sequence.

FIG. 17 is a flowchart showing main processes of Example 3 of the processing sequence.

FIG. 18 is a diagram for explaining the reason why pattern collapse can be suppressed by Example 3 of the processing sequence.

FIG. 19 is a flowchart showing main processes of Example 4 of the processing sequence.

FIG. 20 is a flowchart showing main processes of Example 5 of the processing sequence.

FIG. 21 presents a graph showing comparison of thicknesses of a metal-containing resist film after being subjected to development in two separate cases where radiation of ultraviolet rays is performed and the development is performed using a polar developing material, as in Example of the processing sequence, and where the radiation of ultraviolet rays is not performed and the development is performed using a non-polar developing material.

FIG. 22 is a diagram showing a relationship between CD of a pattern of a metal-containing resist after being subjected to development and an exposure dose.

FIG. 23 is a diagram showing a relationship between the CD of the pattern of the metal-containing resist after being subjected to the development and roughness of the pattern.

FIG. 24 is a diagram showing a relationship between the CD of the pattern of the metal-containing resist after being subjected to the development and a defect ratio.

FIG. 25 is a diagram showing a relationship between CD and an exposure dose when a pattern of a metal-containing resist for a filler having a target width of 18 nm is formed.

FIG. 26 is a diagram showing a relationship between the CD of the pattern of the metal-containing resist after being subjected to development and roughness of the pattern.

FIG. 27 is a diagram showing the CD of the pattern of the metal-containing resist after being subjected to the development and a defect ratio.

FIG. 28 is a flowchart showing main processes of Modification example 1 of Example 5 of the processing sequence.

FIG. 29 is a flowchart showing main processes of Modification example 2 of Example 5 of the processing sequence.

FIG. 30 is a flowchart showing main processes of Modification example 3 of Example 5 of the processing sequence.

### DETAILED DESCRIPTION

In a manufacturing process for a semiconductor device or the like, a series of processes are performed to form a resist pattern on a substrate such as a semiconductor wafer (hereinafter, simply referred to as “wafer”). The series of processes include, by way of example, a resist coating process in which a resist is supplied onto the substrate to form a film of the resist (hereinafter, referred to as a resist film), an exposure process in which the resist film is exposed into a preset pattern, a post exposure bake (PEB) process in which the exposed resist film is heated after the exposure for the purpose of accelerating a chemical reaction within the exposed resist film, a developing process in which the exposed resist film is developed to form a resist pattern, and the like.

Conventionally, a chemically amplified resist has been widely used as the resist, but recently, a negative type metal-containing resist is sometimes used. However, when forming a resist pattern by using the metal-containing resist, scum may remain on the substrate depending on a developing material (for example, an organic solvent) used for the developing process. Furthermore, when a developing material having a high scum removal ability is used, scum is unlikely to remain on the substrate, but the development of the film of the metal-containing resist (hereinafter, referred to as a metal-containing resist film) may progress excessively, that is, the exposure sensitivity of the metal-containing resist film may deteriorate. In addition, if the temperature during the PEB process is increased in order to increase the exposure sensitivity of the metal-containing resist film, the amount of scum remaining on the substrate increases.

In view of this, exemplary embodiments of the present disclosure provide a technique capable of achieving both an increase in the exposure sensitivity of the metal-containing resist film and a decrease in the amount of the scum remaining on the substrate when forming the pattern of the metal-containing resist.

Hereinafter, a substrate processing method and a substrate processing apparatus according to an exemplary embodiment will be described with reference to the accompanying drawings. In the present specification and the drawings, parts having substantially the same functions and configurations will be assigned same reference numerals, and redundant descriptions thereof will be omitted.

### Wafer Processing Apparatus

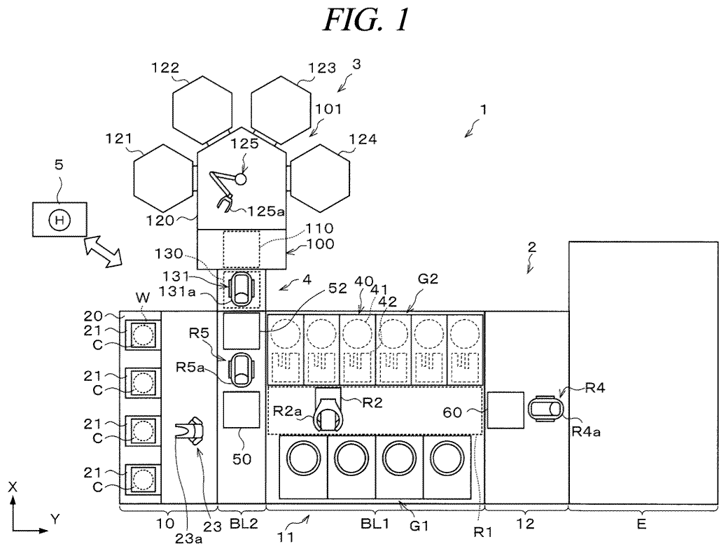

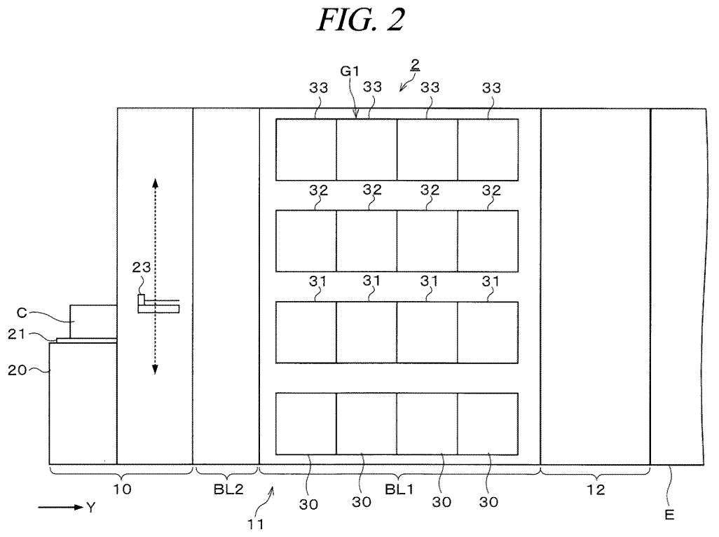

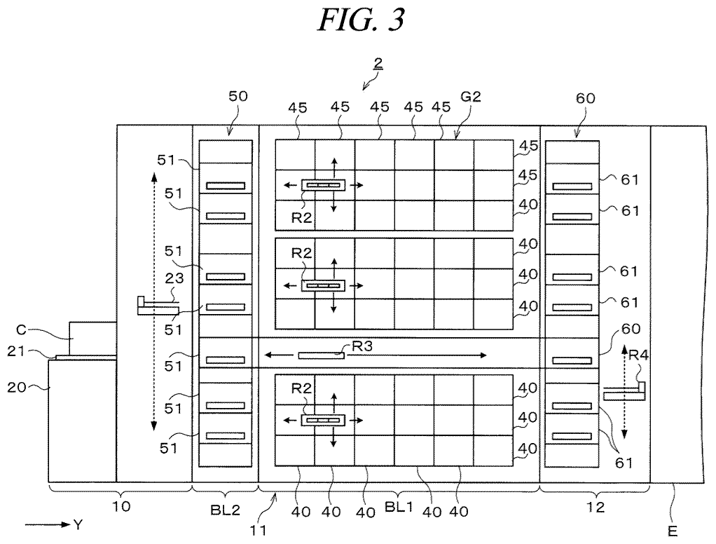

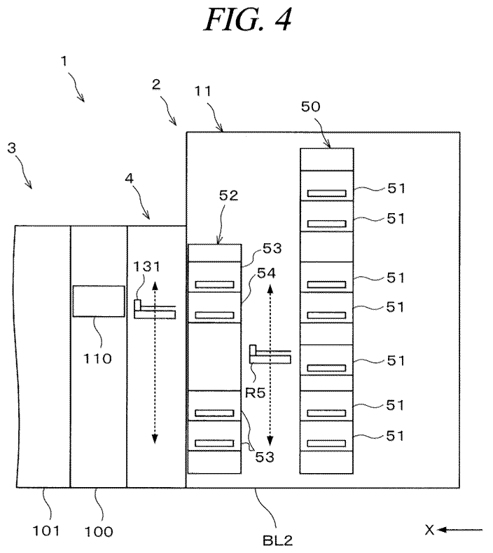

FIG. 1 is an explanatory diagram schematically illustrating an internal configuration of a wafer processing apparatus as a substrate processing apparatus according to the present exemplary embodiment. FIG. 2 and FIG. 3 are diagrams schematically illustrating internal configurations of a front side and a rear side of a wet processing section to be described later, respectively. FIG. 4 is a diagram schematically illustrating a cross section of a delivery block of the wafer processing apparatus of FIG. 1.

A wafer processing apparatus 1 of FIG. 1 is configured to form a pattern of a negative type metal-containing resist on a wafer W as a substrate, specifically, form a pattern of the negative type metal-containing resist having a pitch of 50 nm or less. Though the metal included in the negative type metal-containing resist is not particularly limited, it is a metal constituting a complex in the present exemplary embodiment. As a more specific example, the metal may be tin, hafnium, tellurium, bismuth, indium, antimony, oxo, germanium, or a combination thereof.

The wafer processing apparatus 1 is equipped with, for example, a wet (liquid) processing section 2, a dry (gas) processing section 3, and a relay transfer section 4.

As illustrated in FIG. 1 to FIG. 3, the wet processing section 2 is equipped with a cassette station 10, a processing station 11, and an interface station 12, and is connected to an exposure device E. The exposure device E is configured to perform an exposure process on the wafer W, specifically, perform an exposure process using, for example, extreme ultra-violet (EUV) light. In the wet processing section 2, the cassette station 10, the processing station 11, and the interface station 12 are connected as one body.

In the following, the connection direction between the wet processing section 2 and the exposure device E is referred to as a width direction, and a direction perpendicular to the connection direction, that is, the width direction when viewed from the top is referred to as a depth direction.

The cassette station 10 of the wet processing section 2 is configured to carry in or carry out a cassette C, which is a container configured to accommodate multiple wafers W therein. The cassette station 10 is provided with a cassette placement table 20 at, for example, its end portion on one side in the width direction (negative Y-axis direction in FIG. 1, etc.). A plurality of, e.g., four placement plates 21 are provided on the cassette placement table 20. The placement plates 21 are arranged in a row in the depth direction (X-axis direction in FIG. 1). When carrying the cassette C to/from the outside of the wet processing section 2, the cassette C can be placed on these placement plates 21.

In addition, the cassette station 10 is provided with a transfer module 23 configured to transfer the wafer W on its other side in the width direction (positive Y-axis direction in FIG. 1), for example. The transfer module 23 has a transfer arm 23a configured to be movable in the depth direction (X-axis direction in FIG. 1). The transfer arm 23a of the transfer module 23 is configured to be movable in a vertical direction and around a vertical axis. This transfer module 23 is capable of transferring the wafer W between the cassette C on each placement plate 21 and a delivery module 51 of a delivery tower 50 to be described later.

In addition, the cassette station 10 may be provided with, above the cassette placement table 20 or at a place farther from the exposure device E than the cassette placement table 20 (negative Y-axis portion in FIG. 1), a storage section (not shown) in which the cassette C is placed and stored.

The processing station 11 is equipped with a plurality of processing modules each configured to perform a preset processing such as developing processing.

The processing station 11 is divided into multiple of blocks (two in the example of the drawing) each equipped with various types of modules. A processing block BL1 is provided on the interface station 12 side, and a transfer block BL2 is provided on the cassette station 10 side.

The processing block BL1 has, for example, a first block G1 on its front side (negative X-axis side in FIG. 1) and a second block G2 on its rear side (positive X-axis side in FIG. 1).

By way of example, a plurality of liquid processing modules, for example, a first developing module 30, a second developing module 31, a third developing module 32, and a resist coating module 33 are arranged in this order from the bottom, as shown in FIG. 2. The first to third developing modules 30 to 32 are all wet developing devices that develop the wafer W by a wet method. The resist coating module 33 is a resist coating device that applies a negative type metal-containing resist onto the wafer W to form a metal-containing resist film.

The first developing module 30 develops the wafer W by using a non-polar developing material.

The non-polar developing material is, for example, an organic solvent composed of molecules having an ester structure or an ether structure, or a mixture of the organic solvent and an acidic material.

The organic solvent is, by way of non-limiting example, methyl acetate, butyl acetate, ethyl acetate, isopropyl acetate, amyl acetate, isoamyl acetate, methoxy ethyl acetate, ethoxy ethyl acetate, 2-heptanone, propylene glycol monomethyl ether acetate (PGMEA), isopropyl alcohol, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxy butyl acetate, 3-methoxy butyl acetate, 4-methoxy butyl acetate, 3-methyl-3-methoxy butyl acetate, 3-ethyl-3-methoxy butyl acetate, propylene glycol monoethyl ether acetate, propylene glycol monopropyl ether acetate, 2-ethoxy butyl acetate, 4-ethoxy butyl acetate, 4-propoxy butyl acetate, 2-methoxy pentyl acetate, 3-methoxy pentyl acetate, 4-methoxy pentyl acetate, 2-methyl-3-methoxy pentyl acetate, 3-methyl-3-methoxy pentyl acetate, 3-methyl-4-methoxy pentyl acetate, 4-methyl-4-methoxy pentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, or a combination of two or more of these.

In addition, the acidic material is an organic acid, an inorganic acid, or a combination of the organic and inorganic acids, and the organic acid is, for example, an organic carboxylic acid such as acetic acid or citric acid.

Butyl acetate, 2-heptanone, PEGMEA, or a mixture of any one of these and an organic acid may be appropriately used as the non-polar developing material.

The second developing module 31 develops the wafer W by using a polar developing material.

The polar developing material is, for example, a solution of an alkaline material.

Here, the alkaline material may include, by way of non-limiting example, inorganic alkalis such as sodium hydroxide, potassium hydroxide, sodium carbonate, sodium silicate, sodium metasilicate, and ammonia water; primary amines such as ethylamine and n-propylamine; secondary amines such as diethylamine and di-n-butylamine; tertiary amines such as triethylamine and methyl diethylamine; alcohol amines such as dimethyl ethanol amine and triethanol amine; quaternary ammonium salts such as tetramethylammonium hydroxide, tetraethylammonium hydroxide, tetrabutylammonium hydroxide, tetrapropylammonium hydroxide, methyl triethyl ammonium hydroxide, trimethyl ethyl ammonium hydroxide, dimethyl diethyl ammonium hydroxide, trimethyl(2-hydroxyethyl) ammonium hydroxide (i.e., corrin), triethyl(2-hydroxyethyl) ammonium hydroxide, dimethyl di(2-hydroxyethyl) ammonium hydroxide, diethyl di(2-hydroxyethyl) ammonium hydroxide, methyl tri(2-hydroxyethyl) ammonium hydroxide, ethyl tri(2-hydroxyethyl) ammonium hydroxide, and tetra(2-hydroxyethyl) ammonium hydroxide; cyclic amines such as pyrrole and piperidine; and the like.

In addition, the solvent of the solution of the alkaline material is, for example, water. In this case, alcohol such as isopropyl alcohol or a nonionic surfactant may be added.

Further, alcohol (for example, methanol, ethanol, 1-propanol, 2-propanol, 1-butanol, ethane-1,2-diol, propane-1,2,3-triol, etc.) may be used as the solvent of the solution of the alkaline material.

The polar developing material may also be water. Specifically, the polar developing material may be neutral water or deionized water.

Moreover, the polar developing material may be a mixture of water and an acidic material. The acidic material here is an organic sulfonic acid, an organic carboxylic acid (such as acetic acid or citric acid), an inorganic acid, or a combination thereof.

As the polar developing material, a solution of the quaternary ammonium salt is desirably used, and, more desirably, a solution of the tetraethylammonium hydroxide or a solution of the tetrabutylammonium hydroxide is used. The concentration of the solution of the tetraethylammonium hydroxide or the solution of the tetrabutylammonium hydroxide is desirably in the range of 0.1% to 70% (parts by weight), and, more desirably, in the range of 2% to 10% (parts by weight).

In addition, it is also desirable to use the neutral water or deionized water as the polar developing material for the cost of the material is low, a load on the environment is less, and a rinsing processing after the developing processing can be omitted.

The third developing module 32 develops the wafer W by using a mixture of a non-polar developing material and a polar material.

For example, each of the first to third developing modules 30 to 32 and the resist coating module 33 are plural in number (specifically, four), and the four of each are arranged in the width direction (Y-axis direction in the drawing). Here, the number and the layout of the first to third developing modules 30 to 32 and the resist coating modules 33 can be selected as required.

In each of the first to third developing modules 30 to 32 and the resist coating module 33, a preset processing liquid is applied onto the wafer W by, for example, a spin coating method. In the spin coating, the processing liquid is discharged onto the wafer W from, for example, a discharge nozzle, and the wafer W is rotated to diffuse the processing liquid onto the surface of the wafer W.

Also, each of the first to third developing modules 30 to 32 may be equipped with a rinse nozzle. For example, when the solution of the tetraethyl ammonium hydroxide or the solution of the tetrabutyl ammonium hydroxide is used as the developing material (specifically, as a developing liquid), after the liquid film of the developing liquid is formed on the wafer W by the spin coating, deionized water is discharged as a rinsing liquid onto the wafer W to remove the developing liquid from the wafer W, and, then, the wafer W is rotated to be dried. Further, when the neutral water or deionized water is used as the developing liquid, after a liquid film of the developing liquid is formed on the wafer W by spin coating, the rinsing process may be omitted and the wafer W may be spun to be dried.

For example, in the second block G2, as illustrated in FIG. 3, heat treatment modules 40 and ultraviolet radiation modules 45 are arranged in plural numbers in the vertical direction (up-down direction of the drawing) and the width direction (Y-axis direction of the drawing). The number and the layout of the heat treatment modules 40 and the ultraviolet radiation modules 45 may be selected as required.

By way of example, at least some of the heat treatment modules 40 are a combination of a heating device configured to heat the wafer W and a cooling device configured to cool the wafer W. In the heat treatment module 40, the heating device has a heating plate 41, and the cooling device has a cooling plate 42, as illustrated in FIG. 1. The heating plate 41 is configured to place the wafer W thereon, and a heating element such as a resistance heater is embedded therein. The cooling plate 42 is configured to place the wafer W thereon, and a cooling element such as a flow path for a coolant is embedded therein.

The ultraviolet radiation module 45 is configured to radiate ultraviolet rays to the wafer W. To elaborate, the ultraviolet radiation module 45 radiates the ultraviolet rays to the entire top surface of the wafer W in a moisture-containing atmosphere, that is, radiates the ultraviolet rays to at least the entire device formation region of the wafer W.

As shown in FIG. 1, the processing block BL1 has a transfer path R1 extending in the width direction in a region between the first block G1 and the second block G2. In the processing block BL1, the first to third developing modules 30 to 32 and the resist coating modules 33 are arranged in plural numbers along the transfer path R1 extending in the width direction. A transfer module R2 configured to transfer the wafer W is disposed in the transfer path R1.

The transfer module R2 has a transfer arm R2a configured to be movable in the width direction (Y-axis direction in FIG. 1) and the vertical direction as well as around a vertical axis, for example. The transfer module R2 moves the transfer arm R2a holding the wafer W within a wafer transfer area D, allowing the wafer W to be transferred to a preset device within the first block G1, the second block G2, and preset devices within the delivery tower 50 and a delivery tower 60 to be described later. For example, the transfer module R2 is plural in number, and these transfer modules R2 are vertically arranged, as shown in FIG. 3. Each transfer module R2 is capable of transferring the wafer W to preset modules on approximately the same height within the first block G1, the second block G2, and the delivery towers 50 and 60.

Further, a shuttle transfer module R3 is provided in the transfer path R1 to transfer the wafer W linearly between the delivery tower 50 and the delivery tower 60.

The shuttle transfer module R3 can move the wafer W held thereon linearly in the Y-axis direction to transfer the wafer W between a device of the delivery tower 50 and a device of the delivery tower 60 of approximately the same height.

As depicted in FIG. 1, the delivery block BL2 includes the delivery tower 50 at its central portion in the depth direction (X-axis direction in the drawing). Specifically, in the delivery block BL2, the delivery tower 50 is provided at a position adjacent to the transfer path R1 of the processing block BL1 in the width direction (Y-axis direction in the drawing). In the delivery tower 50, a plurality of delivery modules 51 are arranged to overlap each other in the vertical direction, as shown in FIG. 3.

The interface station 12 is located between the processing station 11 and the exposure device E, as illustrated in FIG. 1, and is configured to deliver the wafer W between them.

In the interface station 12, the delivery tower 60 is disposed at a position adjacent to the transfer path R1 of the processing block BL1 in the width direction (Y-axis direction in the drawing). In the delivery tower 60, a plurality of delivery modules 61 are arranged to overlap each other in the vertical direction, as shown in FIG. 3.

In addition, as shown in FIG. 1, the interface station 12 is further equipped with a transfer module R4.

The transfer module R4 is provided at a position adjacent to the delivery tower 60 in the width direction (Y-axis direction in the drawing), and has a transfer arm R4a configured to be movable in the depth direction (X-axis direction in FIG. 1), in the vertical direction, and around a vertical axis, for example. The transfer module R4 is capable of transferring the wafer W between the plurality of delivery modules 61 of the delivery tower 60 and the exposure device E, while holding the wafer W on the transfer arm R4a.

Further, as shown in FIG. 1, the transfer block BL2 of the processing station 11 has a delivery tower 52 at its end on the rear side (positive X-axis side in the drawing).

The delivery tower 52 has a delivery module 53, as shown in FIG. 4. In the delivery tower 52, the delivery module 53 may be plural in number, and these delivery modules 53 may be arranged to overlap each other in the vertical direction (up-and-down direction in FIG. 4).

In addition, the delivery tower 52 may have a cooling module 54 configured to cool the wafer.

Further, as depicted in FIG. 1, a transfer module R5 is provided in the transfer block BL2. The transfer module R5 is provided between the delivery tower 50 and the delivery tower 52, and has a transfer arm R5a configured to be movable in the vertical direction and around a vertical axis, for example. The transfer module R5 is capable of transferring the wafer W between the plurality of transfer modules 51 of the delivery tower 50, the plurality of transfer modules 53 of the delivery tower 52, and the cooling module 54, while holding the wafer W on the transfer arm R5a.

The dry processing section 3 has a load lock station 100 and a processing station 101, as shown in FIG. 1, for example. In the dry processing section 3, the load lock station 100 and the processing station 101 are connected as one body. In the present exemplary embodiment, the connection direction between the load lock station 100 and the processing station 101 and the connection direction between the wet processing section 2 and the exposure device E are perpendicular to each other, when viewed from the top.

The load lock station 100 is provided with a load lock module 110 configured to be able to switch its internal atmosphere between a decompressed atmosphere and an atmospheric atmosphere.

The processing station 101 has, for example, a vacuum transfer chamber 120, first to third dry developing modules 121 to 123, and a heat treatment module 124.

The vacuum transfer chamber 120 is formed of a housing configured to be hermetically sealable, and the interior of the vacuum transfer chamber 120 is maintained in a decompressed state (vacuum state). The vacuum transfer chamber 120 is formed in, for example, a roughly polygonal shape (pentagon in the example of the drawing) when viewed from the top.

The first to third dry developing modules 121 to 123 are all dry developing devices configured to transfer develop the wafer W by a dry method. While the wet development method uses a liquid, the dry development method uses a gas, and, specifically, uses the gas under reduced pressure.

The first dry developing module 121 develops the wafer W by a dry method, using a non-polar developing material. The non-polar developing material used by the first dry developing module 121 is, for example, a vaporized form of the non-polar developing material exemplified above as being used by the first developing module 30.

The second dry developing module 122 develops the wafer W by a dry method, using a polar developing material. The polar developing material used by the second dry developing module 122 is, for example, a vaporized form of the polar developing material exemplified above as being used by the second developing module 31, hydrogen bromide, boron trichloride, acetic acid (vaporized form), or a combination of two or more of these.

The third dry developing module 123 develops the wafer W by a dry method, using a mixture of the non-polar developing material and the polar material.

The heat treatment module 124 heats the wafer W, that is, performs a heat treatment on the wafer W.

For example, the number of each of the first to third dry developing modules 121 to 123 and the heat treatment module 124 is one.

In the processing station 101, the first to third dry developing modules 121 to 123, the heat treatment module 124, and the load lock station 100 are disposed so as to surround the vacuum transfer chamber 120 when viewed from the top, that is, so as to be arranged around a vertical axis passing through the center of the vacuum transfer chamber 120, for example.

Furthermore, a transfer module 125 configured to transfer the wafer W is provided inside the vacuum transfer chamber 120. The transfer module 125 has a transfer arm 125a configured to be movable around a vertical axis, for example. The transfer module 125 is capable of transferring the wafer between the first to third dry developing modules 121 to 123 and the load lock module 110, while holding the wafer W on the transfer arm 125a.

The relay transfer section 4 is configured to transfer the wafers W between the wet processing section 2 and the dry processing section 3, and, specifically, transfer the wafers W in a wafer unit, i.e., sheet by sheet.

This relay transfer section 4 is provided with a transfer path 130, and is configured to transfer the wafer W between the wet processing section 2 and the dry processing section 3 through this transfer path 130. The transfer path 130 of the relay transfer section 4 constitutes a transfer route that extends in the depth direction (X-axis direction in the drawing) including the delivery tower 50 of the transfer block BL2, etc.

In the present exemplary embodiment, the relay transfer section 4 is connected to a portion of the wet processing section 2 that is farther from the exposure device E than the processing block BL1, specifically, it is connected to the transfer block BL2. More specifically, the transfer path 130 of the relay transfer section 4 is connected to the transfer block BL2.

A transfer module 131 configured to transfer the wafer W is disposed in the transfer path 130.

The transfer module 131 has a transfer arm 131a configured to be movable in the vertical direction and around a vertical axis, for example. The transfer module 131 is capable of transferring the wafer W between the plurality of delivery modules 53 of the delivery tower 52, the cooling module 54, and the load lock module 110, while holding the wafer W on the transfer arm 131a.

In addition, the wafer processing apparatus 1 has a controller 5 that performs a control over the wafer processing apparatus 1, including a control over the transfer modules. The controller 5 is, by way of example, a computer equipped with a processor such as a CPU and a memory, and has a program storage (not shown). The program storage stores therein a program including instructions for a processing sequence to be described later. The program may have been recorded on a non-transitory computer-readable recording medium H, and may be installed into the controller 5 from that recording medium H. The recording medium H may be transitory or non-transitory.

### Example 1 of Processing Sequence

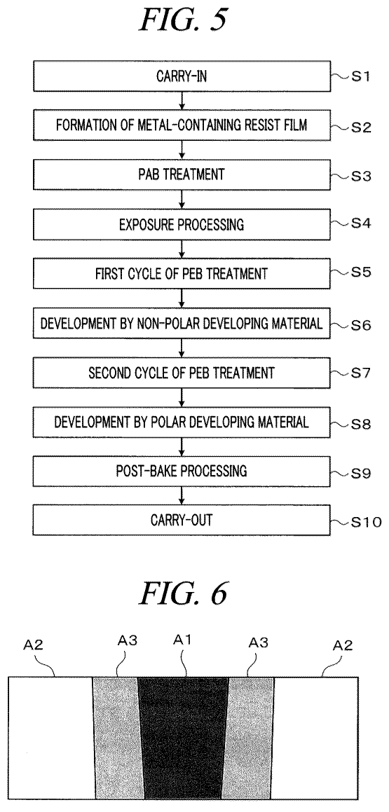

Now, an example of a processing sequence executed by the wafer processing apparatus 1 will be described. FIG. 5 is a flowchart showing main processes of Example 1 of the processing sequence. FIG. 6 is a diagram for explaining an intermediate exposed region to be described later, and it provides a partially enlarged cross sectional view schematically illustrating a metal-containing resist film after being subjected to exposure. In addition, each of the following processes is performed under the control of the controller 5 based on the program stored in the program storage (not shown).

First, the wafer W is carried into the wafer processing apparatus 1 (process S1).

As a specific example, first, the wafer W is taken out from the cassette C on the cassette placement table 20 and transferred to the delivery module 51 of the delivery tower 50 of the transfer block BL2 by the transfer module 23 of the wet processing section 2.

Next, a resist coating processing is performed on the wafer W, so that a metal-containing resist film is formed on the wafer W (process S2).

As a specific example, the wafer W is transferred to the resist coating module 33 of the processing block BL1 by the transfer module R2, and a negative type metal-containing resist is spin-coated on the surface of the wafer W, so that the metal-containing resist film is formed so as to cover the surface of the wafer W. The thickness of the metal-containing resist film thus formed is, for example, 3 nm to 50 nm, and, desirably, 15 nm to 30 nm.

Subsequently, a pre-exposure heating (PAB: Pre-Applied Bake) processing is performed on the wafer W (process S3).

To elaborate, the wafer W is transferred to the heat treatment module 40 for the PAB treatment, and a heating processing is performed on the wafer W. Thereafter, the wafer W is transferred to the delivery module 61 of the delivery tower 60 of the interface station 12.

Subsequently, an exposure processing is performed on the wafer W (process S4).

As a specific example, the wafer W is transferred to the exposure device E by the transfer module R4, and a preset pattern formed on a mask is transcribed to the metal-containing resist film on the wafer W by EUV light. Thereafter, the wafer W is transferred to the delivery module 61 of the delivery tower 60 by the transfer module R4.

Next, the wafer W is subjected to a first post-exposure heating processing (PEB treatment) (process S5).

To elaborate, the wafer W is transferred to the heat treatment module 40 for the first PEB treatment by the transfer module R2, and the wafer W is subjected to a heating processing using the heating plate 41.

Here, the negative type metal-containing resist is in a water-repellent state before the exposure. On the other hand, when the negative type metal-containing resist is exposed to light, an organic ligand of a metal complex (a complex of a metal such as tin, hafnium, tellurium, bismuth, indium, antimony, oxo, or germanium) is released, and the negative type metal-containing resist becomes active. This active metal-containing resist reacts with moisture in the ambient atmosphere, etc., and a hydroxyl group is coupled to the portion from which the ligand has been released, so the metal-containing resist is hydrophilized and becomes a precursor. Then, the metal-containing resists that have become precursors are agglomerated, that is, dehydrated and condensed, so that the metal-containing resist becomes insoluble in the developing material.

The temperature of the wafer W during the first PEB treatment in this process S5 is desirably in the range of 80° C. to 300° C., and, more desirably, in the range of 130° C. to 250° C. The lower the temperature of the wafer W in the first PEB treatment, the smaller the roughness of the pattern surface of the metal-containing resist obtained by Example 1 of the processing sequence may be (that is, dimensional uniformity of micro regions can be improved).

The temperature of the wafer W during the first PEB treatment may be high enough to cause the aforementioned agglomeration, or may be low enough that the aforementioned agglomeration does not occur (or is difficult to occur). Even at a low temperature that does not cause such agglomeration, by performing the first PEB treatment, the state (for example, moisture content, etc.) of the metal-containing resist film on the wafer W at the subsequent process S6 can be suppressed from being non-uniform between the wafers W.

Subsequently, the wafer W is developed by a wet method, using a non-polar developing material (process S6).

As a specific example, the wafer W is transferred to the first developing module 30 by the transfer module R2, and a wet developing processing using the non-polar liquid developing material is performed on the wafer W.

As shown in FIG. 6, in the metal-containing resist film after being subjected to the exposure processing, there exist an exposed region (hereinafter, sometimes referred to as an agglomerated region) A1 that has been exposed and agglomerated as described above, and an unexposed region A2 that has not been exposed and is water-repellent (that is, non-polar). Further, in the metal-containing resist film after being subjected to the exposure processing, there also exists an intermediate exposed region A3 that has been exposed but insufficiently agglomerated due to an insufficient exposure dose or the like. In the intermediate exposed region A3, the metal-containing resist has hydroxyl groups because it is not sufficiently agglomerated even though it has been exposed. As a result, the intermediate exposed region A3 becomes hydrophilic (that is, polar).

By the development using the non-polar developing material in the present process S6, only the water-repellent unexposed region A2 is removed from the metal-containing resist film after being subjected to the exposure processing.

For this reason, the boundary between the water-repellent unexposed region A2 and the hydrophilic intermediate exposed region A3 becomes the surface of the pattern of the metal-containing resist after the present process S6. In the vicinity of the boundary, most of the metal-containing resist is not agglomerated, so it has a small molecular weight. Therefore, the surface of the pattern of the metal-containing resist after the process S6 has small roughness.

Next, a second PEB treatment is performed on the wafer W (process S7).

Specifically, the wafer W is transferred to the heat treatment module 40 for the second PEB treatment by the transfer module R2, and the wafer W is subjected to a heating processing using the heating plate 41.

In Example 1 of the processing sequence, the purpose of the second PEB treatment of the present process S7 is to further advance the agglomeration reaction of the metal-containing resist and solidify the pattern of the metal-containing resist after being subjected to the process S6, thereby suppressing the shape of the pattern of the metal-containing resist after being subjected to the process S6 from being damaged by development in a later process S8.

The temperature of the wafer W in the second PEB treatment is desirably 80° C. to 300° C., and, more desirably, 160° C. to 250° C.

Subsequently, the wafer W is developed by a wet method, using a polar developing material (process S8).

As a specific example, the wafer W is transferred to the second developing module 31 by the transfer module R2, and a wet developing processing using a liquid polar developing material is performed on the wafer W.

By the development using the polar developing material of the present process S8, the insufficiently agglomerated hydrophilic portion is removed from the pattern of the metal-containing resist after being subjected to the process S6.

Thereafter, a post-bake processing is performed on the wafer W (process S9).

Specifically, the wafer W is transferred to the heat treatment module 40 for the second PEB treatment by the transfer module R2, and a heating processing using the heating plate 41 is performed on the wafer W.

Then, the wafer W is carried out from the wafer processing apparatus 1 (process S10).

Specifically, the wafer W is returned back to the cassette C in the reverse order as in the process S1.

This completes the series of processes of the processing sequence.

### Main Effects of Example 1 of Processing Sequence

In Example 1 of the processing sequence, the wafer W having the negative type metal-containing resist film formed thereon and having been subjected to the exposure processing and the PEB treatment is developed by using the polar developing material and the non-polar developing material. Therefore, among unexposed portions or portions with a small exposure dose (hereinafter, referred to as “low-exposure portion”) of the negative type metal-containing resist film, the water-repellent portion that is difficult to remove with the polar developing material can be removed with the non-polar developing material, and, further, the hydrophilic portion that is difficult to remove with the non-polar developing material can be removed with the polar developing material. For this reason, according to Example 1 of the processing sequence, the amount of scum remaining on the wafer W can be reduced as compared to a case where the development is performed by using only the non-polar developing material or only the polar developing material.

In addition, the removing performance of the water-repellent portion by the non-polar developing material and the removing performance of the hydrophilic portion by the polar developing material are unlikely to be affected by the temperature of the wafer W during the PEB treatment.

Thus, in order to increase the exposure sensitivity of the metal-containing resist film, the temperature of the wafer W during the PEB treatment (specifically, the temperature during the second PEB treatment) can be increased.

Therefore, according to Example 1 of the processing sequence, it is possible to achieve both the increase in the exposure sensitivity of the metal-containing resist film and the decrease in the amount of scum remaining on the wafer W during the pattern formation of the metal-containing resist.

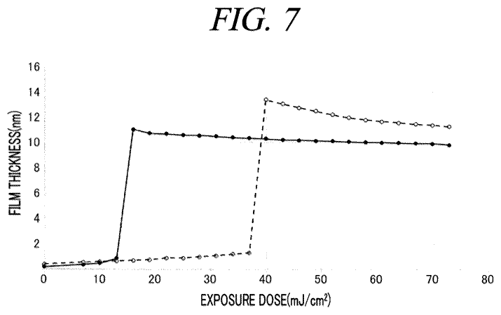

FIG. 7 is a graph that provides comparison of thicknesses of the metal-containing resist film after being subjected to development in two separate cases where development by a polar developing material is performed after development by a non-polar developing material as in Example 1 of the processing sequence and where development by only a non-polar developing material is performed. In the graph, a solid line represents the former case (specifically, the case where a first PEB treatment with a wafer temperature of 160° C. and a heating time of 60 seconds; development by 2-heptanone, which is a non-polar developing material; the second PEB treatment with a wafer temperature of 220° C. and a heating time of 60 seconds, development by an aqueous solution of tetraethylammonium hydroxide, which is a polar developing material; and a post-bake treatment with a wafer temperature of 200° C. and a heating time of 60 seconds are performed in sequence). In addition, in the graph, a dashed line represents the latter case (specifically, the case where a PEB treatment with a wafer temperature of 180° C. and a heating time of 60 seconds; development by a mixture of PGMEA and acetic acid, which is a non-polar developing material; and a post-bake treatment with a wafer temperature of 200° C. and a heating time of 60 seconds are performed in sequence).

As can be clearly seen from this graph, in the case where the development by the polar developing material is performed after the development by the non-polar developing material as in Example 1 of the processing sequence, a metal-containing resist film having a thickness of 10 nm or more can be obtained with a smaller exposure dose as compared to the case where the development by only the non-polar developing material is performed. In this way, according to Example 1 of the processing sequence, the exposure sensitivity of the metal-containing resist film can be increased.

In addition, the present inventors have compared the number of defects when a metal-containing resist pattern of line and space is formed with a target line width of 16 nm and a pitch of 32 nm in the two separate cases where the development by a polar developing material is performed after the development by the non-polar developing material as in Example 1 of the processing sequence and where the development by only the non-polar developing material is performed. As a result of the comparison, the number of defects in the former case is found to be about ⅓ of that in the latter case.

As is clear from this result and the result of FIG. 7, according to Example 1 of the processing sequence, it is possible to achieve both the increase in the exposure sensitivity of the metal-containing resist film and the decrease in the amount of scum remaining on the wafer W when forming the pattern of the metal-containing resist.

In addition, in Example 1 of the processing sequence, after the development by the non-polar developing material of the process S6, the roughness of the surface of the pattern of the metal-containing resist is small. Further, by the second PEB treatment of the process S7, the pattern of the metal-containing resist after being subjected to the development of the process S6 is solidified. For this reason, the surface shape of the pattern is unlikely to be affected by the development by the polar developing material of the process S8. Therefore, the roughness of the surface of the pattern of the metal-containing resist after the development of the process S8, i.e., the roughness of the surface of the pattern of the metal-containing resist that is finally formed is also small.

In addition, when the development is performed by using only the non-polar developing material or only the polar developing material, the boundary between the intermediate exposed region A3 and the exposed region A1 becomes the surface of the pattern of the metal-containing resist after being developed. Also, in the vicinity of this boundary, the metal-containing resist is agglomerated and therefore has a large molecular weight. For this reason, the surface of the pattern of the metal-containing resist after being subjected to the development has a large roughness. In addition, statistical chemical concentration non-uniformity accumulates along with the agglomeration reaction. For this reason, in the case of development using an agglomeration amount of a metal complex, such as development using only the non-polar developing material or only the polar developing material, the roughness tends to be large as compared to development in which polarity change occurs but agglomeration does not occur, such as the development using the non-polar developing material in Example 1 of the processing sequence.

Furthermore, since the energy from the exposure is absorbed in a surface side, that is, an upper portion of the metal-containing resist film, a lower portion of the agglomerated region A1 becomes narrower than the upper portion, that is, the exposed region A becomes narrower at the bottom, as illustrated in FIG. 6. Therefore, if the development is simply performed without taking this into account, the pattern of the metal-containing resist also becomes a shape with a narrow bottom in a cross sectional view, and in this case, especially when the pattern is a filler pattern, there is a risk of pattern collapse.

As a resolution, in Example 1 of the processing sequence, by using a developing material (for example, butyl acetate) having lower polarity as the non-polar developing material when performing the development of the process S6, the shape of the pattern of the metal-containing resist after the process S6 can be suppressed from becoming the shape with the narrow bottom. As a result, the shape of the pattern of the metal-containing resist after the development of the process S8, that is, the pattern of the metal-containing resist that is finally formed may be suppressed from becoming the shape with the narrow bottom. Therefore, according to Example 1 of the processing sequence, the pattern collapse can be suppressed.

Also, the following is assumed as a cause of the pattern collapse. That is, there is a portion on a bottom surface of the agglomerated region A1 or the intermediate exposed region A3 that has a ligand and is in a water-repellent state. For this reason, it is assumed that a low-polarity developing material permeates between the bottom surface of the agglomerated region A1 or the intermediate exposed region A3 and the surface of the wafer W, resulting in the collapse of the pattern of the metal-containing resist after being developed by the low-polarity developing material.

To solve this problem, in Example 1 of the processing sequence, there may be adopted a method in which the exposure dose in the exposure processing is increased, the pattern of the metal-containing resist after being subjected to the development by the non-polar developing material in the process S6 is made thick, and the pattern is made thin by the development with the polar developing material in the process S8. With this method, the pattern collapse can be suppressed.

### Modification Example 1 of Example 1 of Processing Sequence

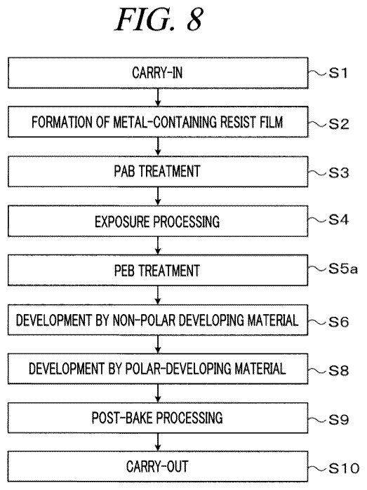

FIG. 8 is a flowchart showing main processes of Modification Example 1 of Example 1 of the processing sequence.

In Example 1 of the processing sequence, the PEB treatment is performed twice. Meanwhile, in this Modification Example 1, the second PEB treatment is omitted, that is, the PEB treatment between the development by the non-polar developing material in the process S6 and the development by the polar developing material in the process S8 is omitted.

Specifically, in this Modification Example 1, after the exposure processing and the PEB treatment of the process S4 in Example 1 of the processing sequence is performed, the only PEB treatment in this processing sequence is performed (process S5a).

Subsequently, the development using the non-polar developing material (hereinafter, sometimes referred to as “non-polar development”) of the process S6 in Example 1 of the processing sequence is performed. Thereafter, without performing the PEB treatment in between, the development using the polar developing material (hereinafter, sometimes referred to as “polar development”) of the process S8 in Example 1 of the processing sequence is performed. Then, the process S9 and the subsequent processes in Example 1 of the processing sequence are carried out.

Furthermore, the temperature of the PEB treatment of the process S5a may be the same as the temperature of the first PEB treatment of the process S5 in Example 1 of the processing sequence. Also, as the temperature of the PEB treatment in the process S5a, a relatively higher temperature range than that of the first PEB treatment may be applied. Specifically, the temperature range may be 180° C. to 220° C.

By setting the temperature of the PEB treatment in the process S5a to be equal to or higher than 180° C., it is possible to suppress the non-polar developing material from permeating between the bottom surface of the agglomerated region A1 or the intermediate exposed region A3 and the surface of the wafer W during the non-polar development in the process S8. Therefore, the pattern collapse can be suppressed. In addition, by setting the temperature to be lower than or equal to 220° C., it is possible to more reliably reduce the amount of scum remaining on the wafer W.

### Main Effects of Modification Example 1 of Example 1 of Processing Sequence

According to Modification Example 1, for the same reason as in Example 1 of the processing sequence, it is possible to achieve both the increase in the exposure sensitivity of the metal-containing resist film and the decrease in the amount of scum remaining on the wafer W when forming the pattern of the metal-containing resist.

In addition, since Modification Example 1 has a smaller number of processes than Example 1 of the processing sequence, high throughput may be achieved. Also, since the heat treatment module 40 for the PEB treatment between the non-polar development and the polar development becomes unnecessary, it is possible to achieve cost reduction as well.

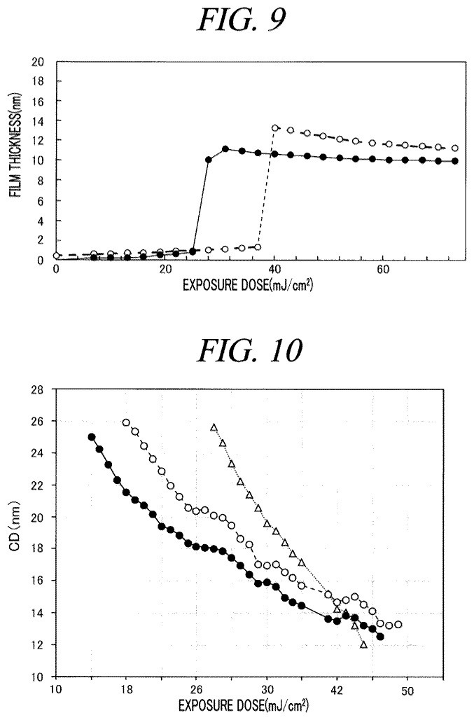

FIG. 9 is a graph showing comparison of thicknesses of the metal-containing resist film after being subjected to the development in two separate cases where the development is performed in the same way as in Modification Example 1 of Example 1 of the processing sequence and where only non-polar development is performed. In the graph, a solid line represents the former case (specifically, the case where a PEB treatment with a wafer temperature of 210° C. and a heating time of 60 seconds, non-polar development using a mixture of PGMEA and acetic acid, and polar development using an aqueous solution of tetraethylammonium hydroxide are performed in sequence). Also, in the graph, a dashed line represents the latter case (specifically, the case where a PEB treatment with a wafer temperature of 180° C. and a heating time of 60 seconds, and non-polar development using a mixture of PGMEA and acetic acid are performed in sequence).

As can be clearly seen from this graph, even when the PEB treatment between the non-polar development and the polar development is omitted as in the case of Modification Example 1 of Example 1 of the processing sequence, a metal-containing resist film having a thickness of 10 nm or more can be obtained with a smaller exposure dose as in the case of Example 1 of the processing sequence, as compared to the case where only the non-polar development is performed. In this way, according to Modification Example 1 of Example 1 of the processing sequence, the exposure sensitivity of the metal-containing resist film can be increased.

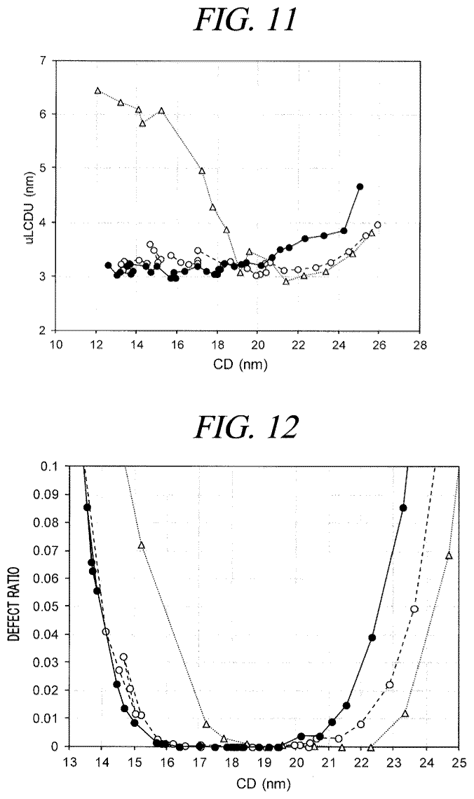

FIG. 10 is a diagram showing a relationship between critical dimension (CD) of the pattern of the metal-containing resist after being subjected to the development (specifically, a hole diameter of a hole pattern with a pitch of 32 nm) and an exposure dose. FIG. 11 is a diagram showing a relationship between the CD and roughness (unbiased local critical dimension uniformity(uLCDU)) of the pattern. FIG. 12 is a diagram showing a relationship between the CD and a defect ratio. In FIG. 10 to FIG. 12, a solid line indicates a case in which the development is performed as in Modification Example 1 of Example 1 of the processing sequence (specifically, the case where a PEB treatment with a wafer temperature of 215° C. and a heating time of 60 seconds, non-polar development using a mixture of PGMEA and acetic acid, and polar development using an aqueous solution of tetraethylammonium hydroxide are performed in sequence). Also, a dashed line indicates a case where the development is performed as in Example 1 of the processing sequence (specifically, the case where a PEB treatment with a wafer temperature of 200° C. and a heating time of 60 seconds, non-polar development using a mixture of PGMEA and acetic acid, a PEB treatment with a wafer temperature of 190° C. and a heating time of 60 seconds, and polar development using an aqueous solution of tetraethylammonium hydroxide, which is a polar developing material, are performed in sequence). In addition, a dotted line indicates a case where only non-polar development is performed (specifically, the case where a PEB treatment with a wafer temperature of 180° C. and a heating time of 60 seconds, and non-polar development using a mixture of PGMEA and acetic acid are performed in sequence).

As is clear from the graph of FIG. 10, when both the non-polar development and the polar development are performed as in the cases of Example 1 and Modification example 1 of the processing sequence, the change in CD with respect to the change in exposure dose is small, that is, exposure dose tolerance of CD is high, as compared to the case where only the non-polar development is performed. In particular, when the PEB treatment between the non-polar development and the polar development is omitted as in Example 1 and Modification Example 1 of the processing sequence, the exposure dose tolerance of CD is higher.

Furthermore, as is apparent from the graph of FIG. 11, when both the non-polar development and the polar development are performed as in the cases of Example 1 and Modification Example 1 of the processing sequence, the roughness of the pattern surface is small in the CD range of 18 nm or less, as compared to the case where only the non-polar development is performed.

Also, as is clear from the graph of FIG. 12, when both the non-polar development and the polar development are performed as in the cases of Example 1 and Modification Example 1 of the processing sequence, the CD range of 20 nm or less where the defect ratio becomes zero is wider than that in the case of performing only the non-polar development. In this way, according to Modification Example 1 of Example 1 of the processing sequence, the amount of scum remaining on the wafer W during the pattern formation of the metal-containing resist can be reduced, the same as in Example 1 of the processing sequence.

### Example of Developing Module in Modification Example 1 of Example 1 of Processing Sequence

When the polar development is performed following the non-polar development, as in Modification Example 1 of Example 1 of the processing sequence, both the non-polar development and the polar development may be performed in one and the same developing module. By performing both the non-polar development and the polar development in the single developing module, the high throughput and the low cost can be achieved.

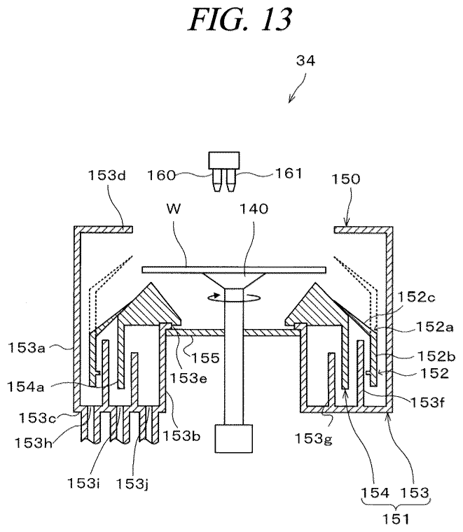

FIG. 13 is a diagram showing an example configuration of a developing module configured to perform both the non-polar development and the polar development.

A developing module 34 of FIG. 13 is provided with a spin chuck 140 configured to hold a wafer W and rotate it around a vertical axis. The spin chuck 140 is configured to be rotatable and movable up and down.

A cup 150 surrounds the wafer W held by the spin chuck 140. The cup 150 is configured to receive and recover a liquid scattering or falling from the wafer W. Details of the cup 150 will be described later.

Further, the developing module 34 is provided with nozzles 160 and 161.

The nozzle 160 is configured to discharge a non-polar developing material. Specifically, the nozzle 160 discharges the non-polar developing material toward the wafer W held by the spin chuck 140.

The nozzle 161 is configured to discharge a polar developing material. Specifically, the nozzle 161 discharges the polar developing material toward the wafer W held by the spin chuck 140.

These nozzles 160 and 161 are configured to be horizontally movable and, also, movable up and down.

The cup 150 has a cup main body 151 and a movable cup 152 configured to movable up and down relative to the cup main body 151.

The cup main body 151 has a cup base body 153 and a fixed cup 154 that is fixed to the cup base body 153.

The cup base body 153 has an annular outer wall 153a and an annular inner wall 153b, and the outer wall 153a and the inner wall 153b are formed to extend in an up-and-down direction (vertical direction). The inner diameter of the outer wall 153a is larger than the diameter of the wafer W, the outer diameter of the inner wall 153b is smaller than the diameter of the wafer W, and the height of the inner wall 153b is lower than the height of the outer wall 153a.

Further, the cup base body 153 has a bottom wall 153c connecting a lower end of the outer wall 153a to a lower end of the inner wall 153b, and an upper wall 153d extending inwards from an upper end of the outer wall 153a. The inner wall 153b has an open top. An inwardly extending protrusion 153e is provided at an upper end of the inner wall 153b, and by interposing this protrusion 153e between the fixed cup 154 and a holding plate 155, the cup base body 153 can be fixed.

The fixed cup 154 constitutes an annular internal structure located between the outer wall 153a and the inner wall 153b. This fixed cup 154 has an annular peripheral wall 154a located between the outer wall 153a and the inner wall 153b.

The movable cup 152 is an annular member configured to be movable up and down between the outer wall 153a of the cup base body 153 and the fixed cup 154, and has a distribution portion 152a at an upper end thereof, and has the peripheral wall 152b under the distribution portion 152a. The distribution portion 152a is for discharging a non-polar developing material and a polar developing material separately, and its top surface is formed as an inclined surface 152c that gradually lowers toward an outer periphery.

The peripheral wall 152b is formed in an annular shape, and its inner diameter is larger than the outer diameter of the peripheral wall 154a of the fixed cup 154, and its outer diameter is smaller than the inner diameter of the outer wall 153a of the cup base body 153. Additionally, an outer peripheral end of the inclined surface 152c of the distribution portion 152a is continuous on an outer peripheral surface of the peripheral wall 152b.

On the bottom wall 153c of the cup base body 153, two partition walls 153f and 153g each having an annular shape are formed between the outer wall 153a and the inner wall 153b.

Further, the bottom wall 153c is provided with, between the outer wall 153a and the partition wall 153f on the outer side, a first collection port 153h for collecting a non-polar developing material. In addition, the bottom wall 153c has a second collection port 153i formed between the partition walls 153f and 153g to collect a polar developing material, and also has a mist collection port 153j formed between the partition wall 153g on the inner side and the inner wall 153b to collect a developing liquid in the form of mist.

Further, in the case of development using a non-polar developing material, the movable cup 152 is lowered, and the non-polar developing material is discharged from the nozzle 161.

Furthermore, a pump connected to the first collection port 153h is driven. As a result, the non-polar developing material scattered due to the rotation of the wafer W and the non-polar developing material that has reached a space under the wafer W and fallen down can be guided into the first collection port 153h from a space between the distribution portion 152a of the movable cup 152 and the outer wall 153a of the cup base body 153, and can be recovered through the collection port 153h.

Meanwhile, in the case of development using a polar developing material, the movable cup 152 is raised, and the polar developing material is discharged from the nozzle 162.

Further, a pump connected to the second collection port 153i is driven. As a result, the polar developing material that has been scattered substantially horizontally due to the rotation of the wafer W can be guided into the second collection port 153i from a space between the distribution portion 152a of the movable cup 152 and the fixed cup 154, and can be recovered through the collection port 153i.

In this way, according to the developing module 34 of FIG. 13, the non-polar developing material and the polar developing material can be collected separately.

### Another Modification Example of Example 1 of Processing Sequence

In Modification Example 1 described above, the (second) PEB treatment performed between the polar development and the non-polar development in Example 1 of the processing sequence is omitted. Instead, however, the first PEB treatment performed before the polar development may be omitted.

### Example 2 of Processing Sequence

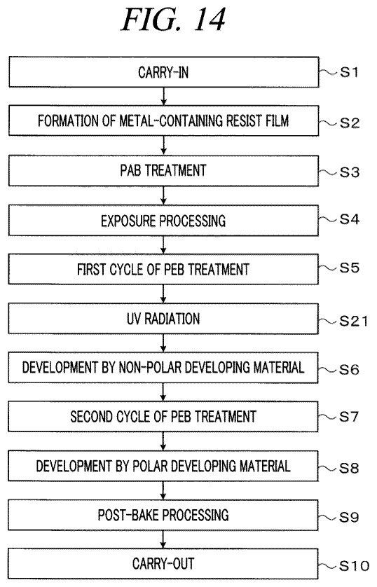

FIG. 14 is a flowchart showing main processes of Example 2 of the processing sequence.

In Example 2 of the processing sequence, after the processes up to the first PEB treatment of the process S5 in Example 1 of the processing sequence are performed, ultraviolet rays are radiated to the entire surface of the wafer W (process S21), as shown in FIG. 14.

To elaborate, the wafer W is transferred to the ultraviolet radiation module 45 by the transfer module R2, and the ultraviolet rays are radiated to the entire surface of the wafer W. At this time, the amount of the ultraviolet radiation may be uniform within the surface of the wafer W or may vary within the surface of the wafer W.

Thereafter, the process S6 and the subsequent processes in Example 1 of the processing sequence are conducted.

### Main Effects of Example 2 of Processing Sequence

In Example 2 of the processing sequence, since the development is performed by using both the polar developing material and the non-polar developing material as in Example 1 of the processing sequence, the amount of scum remaining on the wafer W can be reduced.

Further, the removal performance of the water-repellent portion by the non-polar developing material and the removal performance of the hydrophilic portion by the polar developing material are unlikely to be adversely affected by the ultraviolet radiation of the process S21.

In addition, the exposure sensitivity of the metal-containing resist film can be increased by the ultraviolet radiation of the process S21.

Therefore, according to Example 2 of the processing sequence, it is possible to achieve both the increase in the exposure sensitivity of the metal-containing resist film and the decrease in the amount of scum remaining on the wafer W when forming the pattern of the metal-containing resist.

In addition, in Example 2 of the processing sequence, the surface roughness of the pattern of the metal-containing resist that is finally formed can be reduced, and the pattern collapse can be suppressed, the same as in Example 1 of the processing sequence.

### Modification Examples 1 and 2 of Example 2 of Processing Sequence

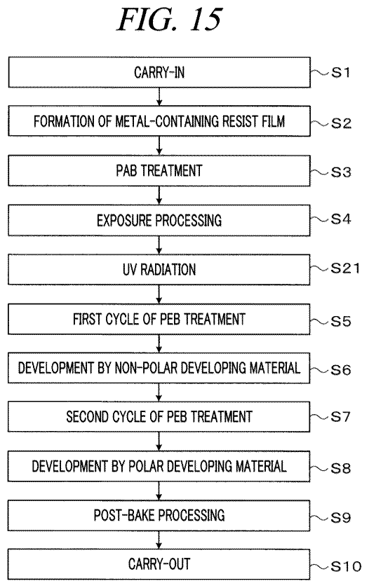

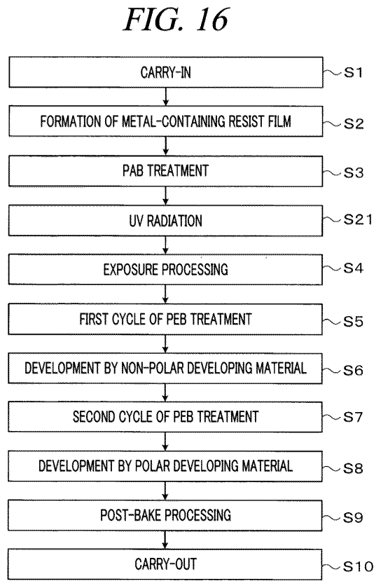

FIG. 15 is a flowchart showing main processes of Modification Example 1 of Example 2 of the processing sequence. FIG. 16 is a flowchart showing main processes of Modification Example 2 of Example 2 of the processing sequence.

In Example 2 of the processing sequence, the ultraviolet radiation to the entire surface of the wafer W of the process S21 is performed after the first PEB treatment in the process S5 but before the development by the non-polar developing material in the process S6. However, the timing at which the process S21 is performed is not limited thereto.

By way of example, the ultraviolet radiation to the entire surface of the wafer W of the process S21 may be carried out after the exposure processing but before the first PEB treatment, as shown in FIG. 15, or may be performed before the exposure processing, specifically after the PAB treatment but before the exposure processing, as shown in FIG. 16.

However, in order to reduce the amount of scum remaining on the wafer W, it is desirable that the ultraviolet radiation to the entire surface of the wafer W of the process S21 is performed after the first PEB treatment in the process S5 but before the development by the non-polar developing material in the process S6. This timing is also desirable in order to increase a difference in dissolution rate between a portion that is removed by the development with the polar developing material and a portion that is not removed, that is, to increase dissolution contrast.

### Modification Example 3 of Example 2 of Processing Sequence

In Example 2 of the processing sequence, the PEB treatment is performed twice. However, the first PEB treatment performed before the development by the non-polar developing material of the process S6 may be omitted.

### Example 3 of Processing Sequence

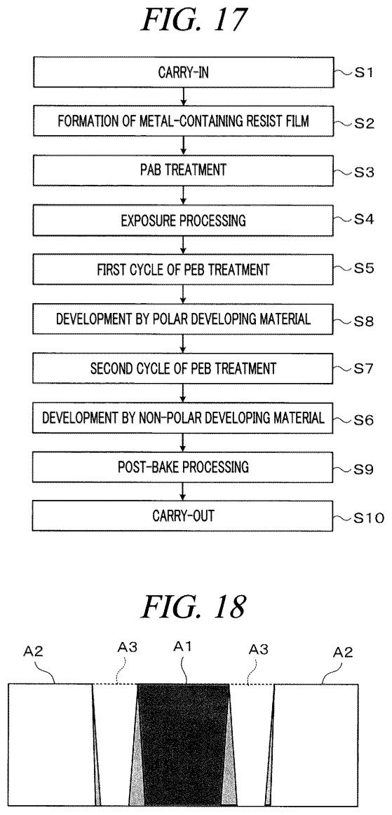

FIG. 17 is a flowchart showing main processes of Example 3 of the processing sequence.

In Example 1 of the processing sequence, etc., the development by the non-polar developing material is performed first, and the development by the polar developing material is performed later. In contrast, in Example 3 of the processing sequence, the development by the polar developing material (process S8) is performed first, and the development by the non-polar developing material (process S6) is performed later, as illustrated in FIG. 17.

To elaborate, after the processes up to the first PEB treatment of the process S5 in Example 1 of the processing sequence are performed, the development is performed by the wet method, using the polar developing material (process S8).

Next, after the second PEB treatment of the process S7 in Example 1 of the processing sequence is performed, the development is performed by the wet method, using the non-polar developing material (process S6).

Thereafter, the post-bake processing is performed on the wafer W (process S9), and the wafer W is carried out from the wafer processing apparatus 1 (process S10).

### Main Effects of Example 3 of Processing Sequence

According to Example 3 of the processing sequence, for the same reason as in Example 1 of the processing sequence, it is possible to achieve both the increase in the exposure sensitivity of the metal-containing resist film and the decrease in the amount of scum remaining on the wafer W when forming a pattern of the metal-containing resist.

FIG. 18 is a diagram explaining the reason why the pattern collapse can be suppressed by Example 3 of the processing sequence.

In addition, in Example 3 of the processing sequence, in the metal-containing resist after being subjected to the development by the polar developing material performed first, a lower portion of the intermediate exposed region A3 on the agglomerated region A1 side can be left, as shown in FIG. 18. This lower portion (light gray portion in the drawing) of the intermediate exposed region A3 on the agglomerated region A1 side can be made insoluble by the second PEB treatment for the non-polar developing material used in the subsequent development. As a result, the shape of the pattern of the metal-containing resist after being subjected to the development by the non-polar developing material in the process S6, that is, the pattern of the metal-containing resist that is finally formed can be suppressed from becoming narrow at the bottom. Therefore, according to Example 3 of the processing sequence, the pattern collapse can be suppressed.

Further, in Example 3 of the processing sequence, in the second PEB treatment after the development by the polar developing material, the adhesion between the bottom surface of the agglomerated region A1 and the surface of the wafer W can be improved. Therefore, the pattern collapse that might occur as a result of the low-polarity developing material permeating between the bottom surface of the water-repellent agglomerated region A1 and the surface of the wafer W.

### Modification Example of Example 3 of Processing Sequence

As in Example 3 of the processing sequence, even in the case where the development by the polar developing material is performed first and the development by the non-polar developing material is performed later, the process of radiating ultraviolet ryas to the entire surface of the wafer W may be performed, as in Example 2 of the processing sequence.

In this case, the timing of the ultraviolet radiation to the entire surface of the wafer W is, for example, after the first PEB treatment in the process S5 and before the development by the non-polar developing material in the process S8, as in Example 2 of the processing sequence. Further, the timing of the ultraviolet radiation to the front surface of the wafer W may be after the exposure processing and before the first PEB treatment, as in Modification Example 1 of Example 2 of the processing sequence, or before the exposure processing, as in Modification Example 2 of Example 2 of the processing sequence.

### Example 4 of Processing Sequence

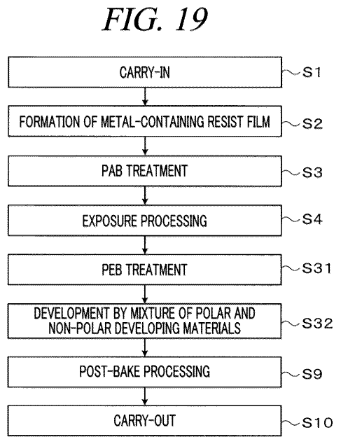

FIG. 19 is a flowchart showing main processes of Example 4 of the processing sequence.

In Examples 1 to 3 of the processing sequence, etc., the development using the non-polar developing material and the development using the polar developing material are performed separately. In Example 4 of the processing sequence, on the other hand, development using a mixture of the non-polar developing material and the polar developing material, that is, a mixed developing material, is performed, as shown in FIG. 19.

To elaborate, after the processes up to the exposure processing of the process S4 in Example 1 of the processing sequence are performed, the PEB treatment is performed on the wafer W (process S31).

As a more specific example, the wafer W is transferred by the transfer module R2 to the heat treatment module 40 for PEB treatment for the mixed developing material, and the heating processing using the heating plate 41 is performed on the wafer W.

Subsequently, development is performed by a wet method, using the mixed developing material (process S32).

Specifically, the wafer W is transferred to the third developing module 32 by the transfer module R2, and a development processing using the aforementioned mixed liquid developing material is performed on the wafer W by a wet method.

Thereafter, a post-bake processing is performed on the wafer W (process S9), and the wafer W is carried out from the wafer processing apparatus 1 (process S10).

### Main Effects of Example 4 of Processing Sequence

According to Example 4 of the processing sequence, for the same reason as in Example 1 of the processing sequence, it is possible to achieve both the increase in the exposure sensitivity of the metal-containing resist film and the decrease in the amount of scum remaining on the wafer W when forming a pattern of the metal-containing resist.

### Modification Example of Example 4 of Processing Sequence

As in Example 4 of the processing sequence, even in the case where the development is performed by the mixture of the non-polar developing material and the polar developing material, that is, the mixed developing material, the process of radiating ultraviolet rays to the entire surface of the wafer W may be performed, as in Example 2 of the processing sequence.

In this case, the timing of the ultraviolet radiation to the entire surface of the wafer W is, for example, after the PEB treatment of the process S31 and before the development by the mixed developing material of the process S32, as in Example 2 of the processing sequence. In addition, the timing of the ultraviolet radiation to the entire surface of the wafer W may be after the exposure processing and before the PEB treatment, as in Modification Example 1 of Example 2 of the processing sequence, or may be before the exposure processing, as in Modification example 2 of Example 2 of the processing sequence.

### Example 5 of Processing Sequence

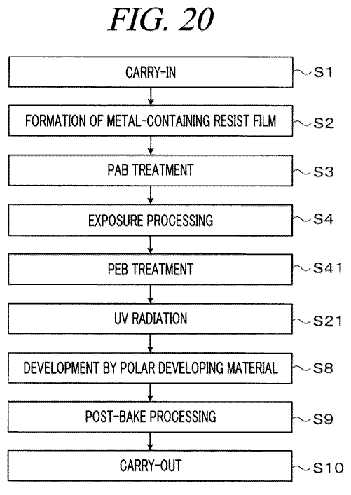

FIG. 20 is a flowchart showing main processes of Example 5 of the processing sequence.

In Example 5 of the processing sequence, after the processes up to the exposure processing of the process S4 in Example 1 of the processing sequence are performed, the wafer W is subjected to a PEB treatment (process S41), as shown in FIG. 20.

Specifically, the wafer W is transferred by the transfer module R2 to the heat treatment module 40 for PEB treatment for Example 5 of the processing sequence, and the heating processing using the heating plate 41 is performed on the wafer W.

Next, the ultraviolet rays are radiated to the entire surface of the wafer W (process S21).

To elaborate, the wafer W is transferred to the ultraviolet radiation module 45 by the transfer module R2, and the ultraviolet rays are radiated to the entire surface of the wafer W. At this time, the amount of the ultraviolet radiation may be uniform within the surface of the wafer W, or may vary within the surface of the wafer W.

By this ultraviolet radiation, in the water-repellent unexposed region A2, the ligand of the metal-containing resist is released, and the hydroxyl group is bonded to that portion from which the ligand has been released. As a result, the unexposed region A2 is hydrophilized and becomes soluble for the polar developing material.

Subsequently, the wafer W is developed by the wet method, using the polar developing material (process S8).

The unexposed region A2 is also made hydrophilic by the ultraviolet radiation of the process S21. Thus, in the metal-containing resist film after being subjected to the exposure processing and the PEB treatment, not only the water-repellent intermediate exposed region A3 but also the unexposed region A2 are removed by the development using the polar developing material of the process S8.

Thereafter, a post-bake processing is performed on the wafer W (process S9), and the wafer W is carried out from the wafer processing apparatus 1 (process S10).

In addition, the wavelength of the ultraviolet rays radiated in the process S21 is, for example, 10 nm or more, and in the case of the wet development as in the present example, it is desirably 160 nm or more. By setting the wavelength of the ultraviolet rays to be 160 nm or more, ozone is not generated even if the ultraviolet radiation is performed in atmospheric atmosphere, so that the development can be suppressed from being affected by the ozone. Further, the wavelength of the ultraviolet rays radiated in the process S21 is, for example, 400 nm or less, and, desirably, 300 nm or less. By setting the wavelength of the ultraviolet rays to be 300 nm or less, the ultraviolet rays can be efficiently absorbed by the metal-containing resist film.

### Main Effects of Example 5 of Processing Sequence

In Example 5 of the processing sequence, the process of radiating the ultraviolet rays to the entire surface of the wafer W having the negative type metal-containing resist film formed thereon, separately from exposure processing, and the process of developing the wafer W, on which the negative type metal-containing resist film is formed and which has been subjected to the exposure processing, the PEB treatment, and the above-described ultraviolet radiation, by the polar developing material are performed.

That is, in Example 5 of the processing sequence, the development by the polar developing material is carried out after the water-repellent unexposed region that is difficult to remove with the polar developing material is hydrophilized and made soluble for the polar developing material by the process of radiating the ultraviolet rays. Therefore, in the metal-containing resist film after being subjected to the exposure processing and the PEB treatment, both the unexposed region A2 and the intermediate exposed region A3 are appropriately removed. Thus, according to Example 1 of the processing sequence, the amount of scum remaining on the wafer W can be reduced, as compared to the case where the development by only the polar developing material is performed.

In addition, the removal performance for the hydrophilic portion by the polar developing material is unlikely to be affected by the temperature of the wafer W during the PEB treatment.

Therefore, in order to increase the exposure sensitivity of the metal-containing resist film, the temperature of the wafer W during the PEB treatment can be increased, and the agglomerated region A1 can be made to be located at an outer side within a range that does not affect CD.

Therefore, according to Example 5 of the processing sequence, it is possible to achieve both the increase in the exposure sensitivity of the metal-containing resist film and the decrease in the amount of scum remaining on the wafer W during pattern formation of the metal-containing resist.

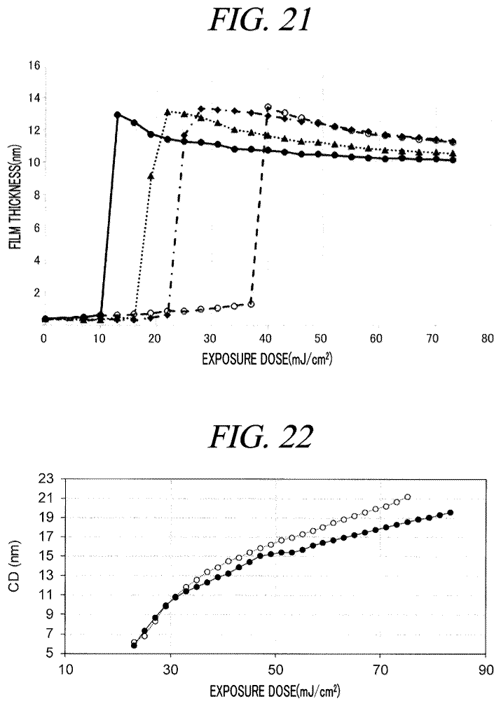

FIG. 21 is a graph that provides comparison of thicknesses of the metal-containing resist film after being subjected to the development in two separate cases where the radiation of ultraviolet rays and the development by the polar developing material are performed, as in Example 5 of the processing sequence, and where the development by the non-polar developing material is performed without performing the radiation of ultraviolet rays. In the graph, a solid line, a dotted line, and a dashed-dotted line represent the former case (specifically, the case where a PEB treatment with a wafer temperature of 180° C. (dashed dotted line), 200° C. (dotted line), or 220° C. (solid line) and a heating time of 60 seconds, ultraviolet radiation with a radiation dose of 40 mJ/cm², development by an aqueous solution of tetraethylammonium hydroxide, which is a polar developing material, and a post-bake treatment with a wafer temperature of 200° C. and a heating time of 60 seconds are performed in sequence). In addition, in the same graph, a dashed line indicates the latter case (specifically, the case where a PEB treatment with a wafer temperature of 180° C. and a heating time of 60 seconds, development using a mixture of PGMEA and acetic acid, which is a non-polar developing material, and a post-bake treatment with a wafer temperature of 200° C. and a heating time of 60 seconds are performed in sequence).

As is clear from this graph, when the radiation of the ultraviolet rays and the development with the polar developing material are performed as in the case of Example 5 of the processing sequence, a metal-containing resist film having a thickness of 10 nm or more can be obtained with a smaller exposure dose during the exposure processing, as compared to the case where the development with the non-polar developing material is performed without performing the radiation of the ultraviolet rays. In this way, according to Example 5 of the processing sequence, the exposure sensitivity of the metal-containing resist film can be increased.

Also, as is apparent from this graph, in the case of performing the development, etc., as in Example 5 of the processing sequence, even if the wafer temperature during the PEB treatment is set to be high, no metal-containing resist remains in the low-exposure region, that is, no scum remains.

In addition, the present inventors have compared the number of defects when a metal-containing resist pattern of line and space is formed with a target line width of 16 nm and a pitch of 32 nm in the two separate cases where the radiation of ultraviolet rays and the development by the polar developing material are performed as in Example 5 of the processing sequence, and where the development by the non-polar developing material is performed without performing the radiation of ultraviolet rays. As a result of the comparison, the number of defects is found to be reduced by about 40% in the former case compared to the latter case.

As is clear from this result and the result of FIG. 21, according to Example 5 of the processing sequence, it is possible to achieve both the increase in the exposure sensitivity of the metal-containing resist film the a decrease in the amount of scum remaining on the wafer W when forming a pattern of the metal-containing resist.

Furthermore, according to Example 5 of the processing sequence, in the metal-containing resist film, the difference in dissolution rate (dissolution contrast) between the portion that is removed by the development by the polar developing material and the portion that is not removed increases due to the ultraviolet radiation. The roughness of the surface of the pattern of the metal-containing resist formed by the development with the polar developing material is inversely proportional to the contrast of this dissolution rate. Therefore, according to Example 5 of the processing sequence, the roughness of the surface of the pattern of the metal-containing resist after development can be reduced.

Moreover, since the developing material is the polar developing material, it is difficult for the developing material to permeate between the bottom surface of the water-repellent agglomerated region A1 and the surface of the wafer W. Therefore, according to Example 5 of the processing sequence, the pattern collapse can be suppressed.

Additionally, in Example 5 of the processing sequence, the ultraviolet radiation and the polar development are performed by the wafer processing apparatus 1 without taking out the wafer W to be processed from the wafer processing apparatus 1. That is, the ultraviolet radiation and the polar development are performed inline. Therefore, the time from the end of the ultraviolet radiation to the start of the polar development is short, for example, within 10 minutes. Therefore, it is possible to suppress the atmosphere around the wafer W from affecting the polar development during the period from the end of the ultraviolet radiation to the start of polar development.

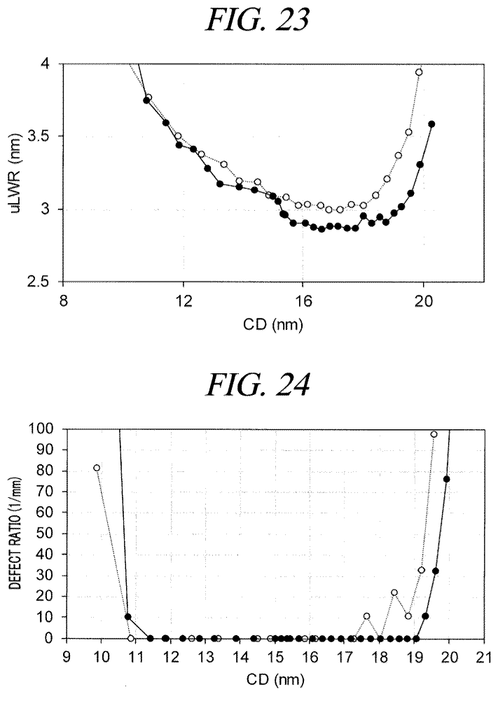

FIG. 22 is a diagram showing a relationship between CD (specifically, line width) and an exposure dose when the line-and-space pattern of the metal-containing resist with the target line width of 16 nm and the pitch of 32 nm is formed. FIG. 23 is a diagram showing a relationship between the CD and roughness (unbiased line width roughness (uLWR)) of the pattern. FIG. 24 is a diagram showing a relationship between the CD and a defect ratio. In FIG. 22 to FIG. 24, a solid line indicates a case where development is performed in the same manner as in Example 5 of the processing sequence (specifically, a PEB treatment with a wafer temperature of 200° C. and a heating time of 60 seconds, ultraviolet radiation with a wavelength of 248 nm and a radiation dose of 70 mJ/cm², and polar development by tetraethylammonium hydroxide are performed in sequence). Also, a dotted line indicates a case where only non-polar development is performed without ultraviolet radiation (specifically, a PEB treatment with a wafer temperature of 180° C. and a heating time of 60 seconds, and non-polar development by a mixture of PGMEA and acetic acid are performed in sequence).

As is clear from the graph of FIG. 22, in the case where the ultraviolet radiation and the polar development are performed in sequence as in Example 5 of the processing sequence, the variation in CD with respect to the variation in exposure dose is small, that is, the exposure dose tolerance of CD is high, as compared to the case where the non-polar development is performed without performing the ultraviolet radiation.

In addition, as is apparent from the graph of FIG. 23, in the case where the ultraviolet radiation and the polar development are performed in sequence as in Example 5 of the processing sequence, the roughness of the pattern surface is small in the CD range of 20 nm or less, as compared to the case where the non-polar development is performed without performing the ultraviolet radiation.

Moreover, as can be clearly seen from the graph of FIG. 24, in the case where the ultraviolet radiation and the polar development are performed in sequence as in the case of Example 5 of the processing sequence, the CD range of 19 nm or less where the defect ratio becomes zero is wider, as compared to the case where the non-polar development is performed without performing the ultraviolet radiation.

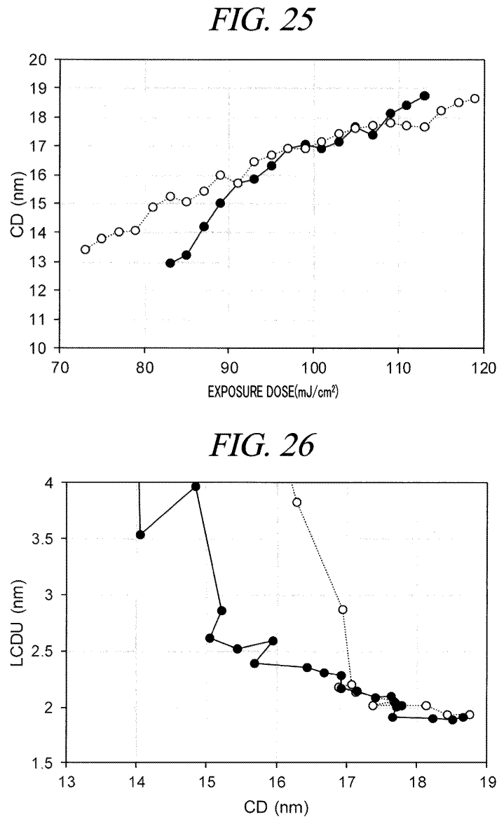

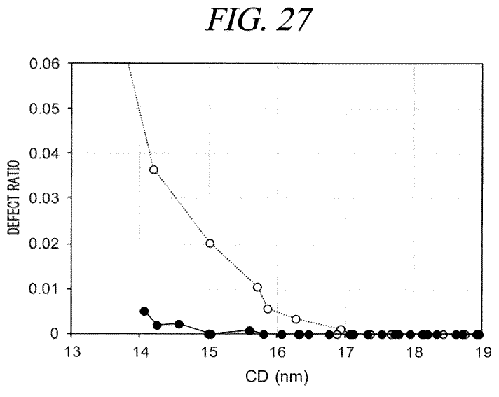

FIG. 25 is a diagram showing a relationship between CD (specifically, filler width) and an exposure dose when a metal-containing resist pattern of a filler having a target width of 18 nm is formed. FIG. 26 is a diagram showing a relationship between the CD and the roughness (uLCDU) of the pattern. FIG. 27 is a diagram showing a relationship between the CD and a defect ratio. In FIG. 25 to FIG. 27, a solid line represents a case where development is performed in the same manner as in Example 5 of the processing sequence (specifically, a case where a PEB treatment with a wafer temperature of 160° C. and a heating time of 60 seconds, ultraviolet radiation with a wavelength of 248 nm and a radiation dose of 50 mJ/cm², and polar development by deionized water are performed in sequence). Also, a dotted line indicates a case where only non-polar development is performed without performing ultraviolet radiation (specifically, a case where a PEB treatment with a wafer temperature of 160° C. and a heating time of 60 seconds, and non-polar development by a mixture of PGMEA and acetic acid are performed in sequence).

As can be clearly seen from the graph of FIG. 25, in the case where the ultraviolet radiation and the polar development are performed in sequence as in Example 5 of the processing sequence and the deionized water is used, the variation in CD with respect to the variation in exposure dose is small, that is, the exposure dose tolerance of CD is high, as compared to the case where the non-polar development is performed without performing the ultraviolet radiation. Specifically, the exposure dose tolerance is found to be improved by 55%.

In addition, as is clear from the graph of FIG. 26, in the case where the ultraviolet radiation and the polar development are performed in sequence as in Example 5 of the processing sequence and the deionized water is used, the roughness of the pattern surface is small in the CD range of 20 nm or less, as compared to the case where the non-polar development is performed without performing the ultraviolet radiation.

Furthermore, as is apparent from the graph of FIG. 27, in the case where the ultraviolet radiation and the polar development are performed in sequence as in Example 5 of the processing sequence and the deionized water is used, the CD range of 19 nm or less where the defect ratio becomes zero is wider, as compared to the case where the non-polar development is performed without performing the ultraviolet radiation. Specifically, in the case where the non-polar development is performed without the ultraviolet radiation, the pattern collapse is found to occur in the filler pattern having the CD of 17 nm or less. In contrast, when the ultraviolet radiation and the polar development are performed in sequence as in Example 5 of the processing sequence and the deionized water is used, the pattern collapse does not occur even in the filler pattern of 15 nm. It is assumed that the pattern collapse is suppressed because the deionized water, which is the developing liquid, has difficulty in permeating and reaching a bottom (water repellent) of the resist.

In addition, using an aqueous developing material such as the deionized water rather than the aqueous solution of tetraethyl ammonium hydroxide as the non-polar developing material can suppress an impact on the environment.

### Modification Examples 1 and 2 of Example 5 of Processing Sequence

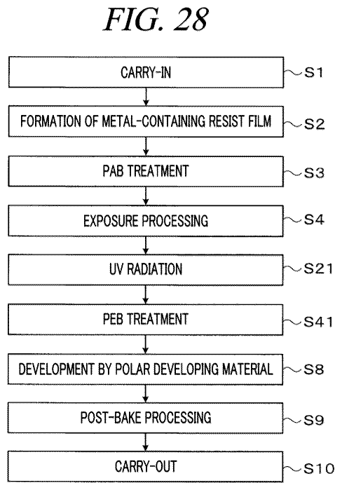

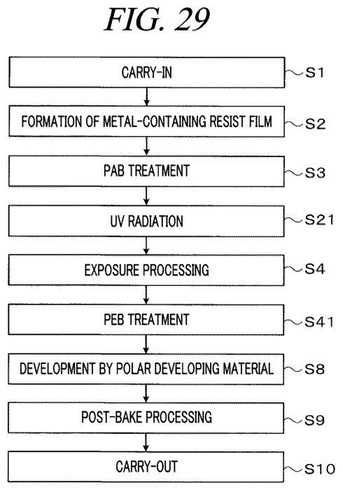

FIG. 28 is a flowchart showing main processes of Modification example 1 of Example 5 of the processing sequence. FIG. 29 is a flowchart showing main processes of Modification example 2 of Example 5 of the processing sequence.

In Example 5 of the processing sequence, the ultraviolet radiation to the entire surface of the wafer W of the process S21 is performed after the PEB treatment in the process S41 and before the development by the polar developing material in the process S8. However, the timing at which the process S21 is performed is not limited thereto.

By way of example, the ultraviolet radiation to the entire surface of the wafer W of the process S21 may be performed after the exposure processing but before the PEB treatment, as shown in FIG. 28, or may be performed before the exposure processing, specifically, after the PAB treatment but before the exposure processing, as shown in FIG. 29.

However, in order to reduce the amount of scum remaining on the wafer W, it is desirable that the ultraviolet radiation to the entire surface of the wafer W of the process S21 is performed after the PEB treatment in the process S41 but before the development by the polar developing material in the process S8. This timing is also desirable in order to increase the difference in dissolution rate, that is, the contrast between the portion that is removed by the development with the polar developing material and the portion that is not removed.

### Modification Example 3 of Example 5 of Processing Sequence

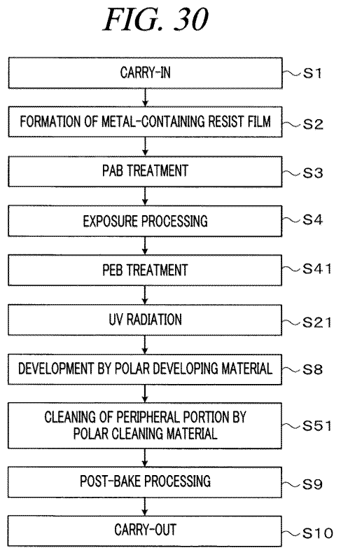

FIG. 30 is a flowchart showing main processes of Modification Example 3 of Example 5 of the processing sequence.

In this Modification Example 3, cleaning of a peripheral portion of the wafer W with a polar cleaning liquid is performed by the second developing module 31 concurrently with or following the polar development in the process S8 after the ultraviolet radiation in the process S21, without moving the wafer W (process S51) in between. That is, in the polar development of process S8 and the polar cleaning of the peripheral portion of the wafer W, the developing module is shared. Specifically, a cup (not shown) for collecting the processing liquid applied to the wafer W is shared. Therefore, since the number of modules mounted to the wet processing section 2 can be reduced, the footprint of the wet processing section 2 can be reduced.

When development of a metal-containing resist is performed, a metal may remain on a peripheral portion of a wafer. As a way to remove this metal, a method using a cleaning solution having a higher acid concentration than a developing liquid, or a method of supplying a solvent in the developing liquid as the cleaning liquid may be considered, for example. However, the cleaning liquid in the former method is of a high price. In addition, in the latter method, it is difficult to remove the metal unless a large amount of the cleaning liquid is used.

In Modification example 3 as well, a metal may remain on the peripheral portion of the wafer after being subjected to the development. However, in the present Modification example 3, since the ultraviolet radiation is performed before the development and the polar cleaning of the peripheral portion of the wafer W, the resist film on the peripheral portion of the wafer W is hydrophilized, so that the metal can be removed as a hydrophilic substance by using a relatively inexpensive polar cleaning liquid such as an aqueous cleaning liquid. Furthermore, since the hydrophilic substance is easily rinsed away with the polar cleaning liquid, the amount of the cleaning liquid required for the removal of the metal can be reduced.

In addition, by using the same material as the developing material used for the polar development and as the cleaning liquid used for the cleaning of the peripheral portion of the wafer, or by using the aqueous material as the cleaning liquid, the developing material and the cleaning liquid collected from the cup in the developing module can be discharged through one and the same waste liquid line.

Besides, in this Modification example 3, the ultraviolet radiation may be performed so that the bevel of the wafer W is also irradiated with the ultraviolet rays. Accordingly, since the resist film on the bevel can be hydrophilized, the remaining of the metal on the bevel can be further suppressed during the polar cleaning of the peripheral portion of the wafer W.

Additionally, in Modification example 3, after the process S51, the process S9 and the subsequent processes in Example 1 of the processing sequence are performed.

In the above, the cleaning by the polar cleaning liquid is performed on the peripheral portion of the wafer W. However, this cleaning by the polar cleaning liquid may be performed on the peripheral portion of the wafer W after performing cleaning by a non-polar cleaning liquid first. Alternatively, cleaning by a mixture of the polar cleaning liquid and the non-polar cleaning liquid may be performed on the peripheral portion of the wafer W.

In addition, the cleaning target may be only the front surface side of the peripheral portion of the wafer W, or both the front surface side and the rear surface side of the peripheral portion of the wafer W.

Further, the cleaning target is not limited to the peripheral portion of the wafer W, and may be the entire rear surface of the wafer W.

Additionally, the cleaning material used for the cleaning of the wafer W is not limited to the polar cleaning liquid, that is, not limited to the polar liquid but may be a polar gas. The polar gas as the cleaning material may be, by way of example, the same gas as the one for dry development.

### Other Modification Examples of Examples 1 to 5 of Processing Sequence

In the above-described Examples 1 to 5 of processing sequence and their Modification examples, the wet development was performed as the development, but part or all of the development of each processing sequence may be performed as the dry development. When the dry development is performed, the dry developing module (121 to 123) is used depending on the type of developing material used in the development.

In addition, when the dry development is performed, the heat treatment for the wafer W performed before and after the dry development may be performed in the heat treatment module 124.

In addition, the dry development may be performed outside the wafer processing apparatus 1. However, including the case of Example 5 of processing sequence, it is preferable that the dry development and each other process constituting each processing sequence are all performed within the wafer processing apparatus 1, i.e., inline. This can shorten the time before the start of dry development, and as a result, the atmosphere around the wafer W until the start of dry development can be suppressed from affecting the dry development.

In addition, in Example 5 of the processing sequence, if the polar development is performed by the dry development method, that is, by using a gas under reduced pressure, the ultraviolet radiation may also be performed under the reduced pressure. In this case, the ultraviolet rays to be radiated may be vacuum ultraviolet rays, that is, its wavelength may be in the range of, e.g., 10 nm to 200 nm. When the ultraviolet radiation is performed under the reduced pressure, plasma formed in a module in which the dry development is performed may be used as a light source for the ultraviolet rays.

Further, although the dry method is mentioned above as a method using the gas under the reduced pressure, it may be a method using a gas under an atmospheric pressure. When the development is performed by using a gas under the atmospheric pressure, a developing processing module may be provided in the wet processing section 2 under an atmospheric atmosphere, not the dry processing section 3 under a decompressed atmosphere.

Not only in Example 5 of the processing sequence but also in Examples 1 to 4 of the processing sequence, the cleaning of the wafer W may be performed during or following the development (i.e., immediately after the development).

The timing for performing the cleaning of the wafer W is not limited to during or immediately after the development. Since there is a possibility that the wafer W may be contaminated with the metal after the formation of the resist film, after the heat treatment, or after the exposure, the cleaning of the wafer W may be performed following at least one of these processings.

In addition, the cleaning of the wafer W may be performed after ultraviolet radiation is performed only on a portion (such as a front surface peripheral portion of the wafer W or a rear surface peripheral portion of the wafer W, the entire rear surface of the wafer W, etc.) other than the region where the resist pattern is to be formed (hereinafter, a pattern formation region). This method is effective when there is no need to radiate ultraviolet rays to the resist pattern region. For example, when forming the resist pattern according to Example 1 of the processing sequence, ultraviolet radiation to the resist pattern region is unnecessary.

Besides, in the examples of the processing sequence described above, development other than the above-described developments may be additionally performed. The additionally performed development may be either the wet development or the dry development.

In the case where the dry development is performed, the dry development may be performed repeatedly.

Additionally, the metal-containing resist film may be formed by a CVD method or an ALD method. In this case, the formation of the metal-containing resist film is performed outside the wafer processing apparatus 1, for example.

In each of the above-described examples of the processing sequence, instead of the PAB treatment, another treatment in which the solvent in the metal-containing resist film is vaporized, for example, natural drying or reduced pressure drying may be performed.

In addition, for the processing sequence in which the PEB treatment is performed multiple times, the first PEB treatment may be performed outside the wafer processing apparatus 1. Also, for the processing sequence in which the PEB treatment is performed only once, the PEB treatment may be performed outside the wafer processing apparatus 1.

The post-bake processing may be omitted.

### Modification Example of Wafer Processing Apparatus 1

Depending on the processing sequence performed by the wafer processing apparatus 1, the components of the wafer processing apparatus 1 may be appropriately omitted. That is, when the wafer processing apparatus 1 performs only a part of the examples of the processing sequence described above, the components of the wafer processing apparatus 1 that are not used in the corresponding processing sequence may be omitted.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

Further, the following configuration examples are also included in the technical scope of the present disclosure.

(1) A substrate processing method, including:
developing, using a polar developing material and a non-polar developing material, a substrate on which a film of a negative type metal-containing resist is formed and on which an exposure processing and a heating processing after the exposure processing are performed.

(2) The substrate processing method described in (1),
wherein the developing of the substrate includes:
developing the substrate by using a first one of the polar developing material and the non-polar developing material; and
developing the substrate by using a second one of the polar developing material and the non-polar developing material.

(3) The substrate processing method described in (2),
wherein the first one is the non-polar developing material, and the second one is the polar developing material.

(4) The substrate processing method described in (3), further including:
performing the heating processing after the exposure processing on the substrate on which the film of the metal-containing resist is formed and on which the exposure processing is performed,
wherein the performing of the heating processing after the exposure processing includes performing the heating processing after the exposure processing between the developing of the substrate by using the first one of the polar developing material and the non-polar developing material and the developing of the substrate by using the second one of the polar developing material and the non-polar developing material.

(5) The substrate processing method described in (4),
wherein the performing of the heating processing after the exposure processing includes performing the heating processing after the exposure processing before the developing of the substrate by using the first one of the polar developing material and the non-polar developing material.

(6) The substrate processing method described in (2),
wherein the first one is the polar developing material, and the second one is the non-polar developing material.

(7) The substrate processing method described in (6), further including:
performing the heating processing after the exposure processing on the substrate on which the film of the metal-containing resist is formed and on which the exposure processing is performed,
wherein the performing of the heating processing includes:
performing, before the developing of the substrate by using the first one of the polar developing material and the non-polar developing material, a first cycle of the heating processing after the exposure processing; and
performing, between the developing of the substrate by using the first one of the polar developing material and the non-polar developing material and the developing of the substrate by using the second one of the polar developing material and the non-polar developing material, a second cycle of the heating processing after the exposure processing.

(8) The substrate processing method described in (1),
wherein the developing is performed by a mixture of the polar developing material and the non-polar developing material.

(9) The substrate processing method described in any one of (1) to (4) and (6) to (8), further including:
radiating, before or after the exposure processing on the substrate, an ultraviolet ray to an entire surface of the substrate on which the film of the metal-containing resist is formed.

(10) The substrate processing method described in (5), further including:
radiating an ultraviolet ray to an entire surface of the substrate before the developing of the substrate by using the first one of the polar developing material and the non-polar developing material and after the performing of the heating processing after the exposure processing before the developing of the substrate by using the first one of the polar developing material and the non-polar developing material.

(11) The substrate processing method described in any one of (1) to (10),
wherein the polar developing material is a solution of an alkaline material, water, a solution of an acidic material, or a vaporized material of any one of the solution of the alkaline material, the water, and the solution of the acidic material.

(12) The substrate processing method described in any one of (1) to (11),
wherein the non-polar developing material is an organic solvent composed of molecules having an ester structure or an ether structure, a mixture of the organic solvent and an acidic material, or a vaporized material of any one of the organic solvent and the mixture of the organic solvent and the acidic material.

(13) The substrate processing method described in any one of (1) to (12),
wherein a metal contained in the metal-containing resist is tin.

(14) The substrate processing method described in any one of (1) to (13),
wherein a pattern of the metal-containing resist having a pitch of 50 nm or less is formed by the developing.

(15) A substrate processing method, including:
radiating an ultraviolet ray to an entire surface of a substrate on which a film of a negative type metal-containing resist is formed, before or after an exposure processing on the substrate; and
developing, using a polar developing material, the substrate on which the film is formed and on which the exposure processing, a heating processing after the exposure processing, and the radiating of the ultraviolet ray are performed.

(16) The substrate processing method described in (15), further including:
performing, before the developing, the heating processing after the exposure processing on the substrate on which the film is formed and on which the exposure processing is performed,
wherein the radiating of the ultraviolet ray is performed after the performing of the heating processing after the exposure processing.

(17) The substrate processing method described in (15) or (16),
wherein the polar developing material is a solution of an alkaline material, water, a solution of an acidic material, or a vaporized material of any one of the solution of the alkaline material, the water, and the solution of the acidic material.

(18) The substrate processing method described in any one of (15) to (17),
wherein a metal contained in the metal-containing resist is tin.

(19) The substrate processing method described in any one of (15) to (18),
wherein a pattern of the metal-containing resist having a pitch of 50 nm or less is formed by the developing.

(20) A substrate processing apparatus configured to process a substrate, including:
a developing device configured to develop the substrate, using a polar developing material and a non-polar developing material; and
a controller,
wherein the controller controls the substrate processing apparatus to develop the substrate on which a film of a negative type metal-containing resist is formed and on which an exposure processing and a heating processing after the exposure processing are performed, using the polar developing material and the non-polar developing material.

(21) The substrate processing method described in (6), further including:
performing the heating processing after the exposure processing on the substrate on which the film of the metal-containing resist is formed and on which the exposure processing is performed,
wherein the heating processing after the exposure processing is performed only before the developing of the substrate by using the first one of the polar developing material and the non-polar developing material.

(22) The substrate processing method described in any one of (15) to (19), further including:
cleaning, during the developing or following the developing, a peripheral portion of the substrate by using a polar cleaning material.

### EXPLANATION OF CODES

1: Wafer processing apparatus
5: Controller
30: First developing module
31: Second developing module
32: Third developing module
120: Vacuum transfer chamber
121: First dry developing module
122: Second dry developing module
123: Third dry developing module
W: Wafer

1. A substrate processing method, comprising:
developing, using a polar developing material and a non-polar developing material, a substrate on which a film of a negative type metal-containing resist is formed.

2. The substrate processing method of claim 1,
wherein the developing of the substrate comprises:
developing the substrate by using a first one of the polar developing material and the non-polar developing material; and
developing the substrate by using a second one of the polar developing material and the non-polar developing material.

3. The substrate processing method of claim 2,
wherein the first one is the non-polar developing material, and the second one is the polar developing material.

4. The substrate processing method of claim 3, further comprising:
performing exposure processing; and
performing a heating processing after the exposure processing
wherein the heating processing is performed after the exposure processing and between the developing of the substrate by using the first one of the polar developing material and the non-polar developing material and the developing of the substrate by using the second one of the polar developing material and the non-polar developing material.

5. The substrate processing method of claim 4,
wherein the performing of the heating processing after the exposure processing comprises performing the heating processing after the exposure processing before the developing of the substrate by using the first one of the polar developing material and the non-polar developing material.

6. The substrate processing method of claim 2,
wherein the first one is the polar developing material, and the second one is the non-polar developing material.

7. The substrate processing method of claim 6, further comprising:
performing exposure processing; and
performing a heating processing after the exposure processing on the substrate on which the film of the metal-containing resist is formed and on which the exposure processing is performed,
wherein the performing of the heating processing comprises:
performing, before the developing of the substrate by using the first one of the polar developing material and the non-polar developing material, a first cycle of the heating processing after the exposure processing; and
performing, between the developing of the substrate by using the first one of the polar developing material and the non-polar developing material and the developing of the substrate by using the second one of the polar developing material and the non-polar developing material, a second cycle of the heating processing after the exposure processing.

8. The substrate processing method of claim 1,
wherein the developing is performed by a mixture of the polar developing material and the non-polar developing material.

9. The substrate processing method of claim 1, further comprising:
performing exposure processing; and
radiating, before or after the exposure processing on the substrate, an ultraviolet ray to an entire surface of the substrate on which the film of the metal-containing resist is formed.

10. The substrate processing method of claim 5, further comprising:
radiating an ultraviolet ray to an entire surface of the substrate before the developing of the substrate by using the first one of the polar developing material and the non-polar developing material and after the performing of the heating processing after the exposure processing before the developing of the substrate by using the first one of the polar developing material and the non-polar developing material.

11. The substrate processing method of claim 1,
wherein the polar developing material is a solution of an alkaline material, water, a solution of an acidic material, or a vaporized material of any one of the solution of the alkaline material, the water, and the solution of the acidic material.

12. The substrate processing method of claim 1,
wherein the non-polar developing material is an organic solvent composed of molecules having an ester structure or an ether structure, a mixture of the organic solvent and an acidic material, or a vaporized material of any one of the organic solvent and the mixture of the organic solvent and the acidic material.

13. The substrate processing method of claim 1,
wherein a metal contained in the metal-containing resist is tin.

14. The substrate processing method of claim 1,
wherein a pattern of the metal-containing resist having a pitch of 50 nm or less is formed by the developing.

15. A substrate processing method, comprising:
performing exposure processing;
radiating an ultraviolet ray to an entire surface of a substrate on which a film of a negative type metal-containing resist is formed, before or after the exposure processing on the substrate; and
developing, using a polar developing material, the substrate on which the film is formed.

16. The substrate processing method of claim 15, further comprising:
performing, before the developing, a heating processing after the exposure processing on the substrate on which the film is formed,
wherein the radiating of the ultraviolet ray is performed after the performing of the heating processing after the exposure processing.

17. The substrate processing method of claim 15,
wherein the polar developing material is a solution of an alkaline material, water, a solution of an acidic material, or a vaporized material of any one of the solution of the alkaline material, the water, and the solution of the acidic material.

18. The substrate processing method of claim 15,
wherein a metal contained in the metal-containing resist is tin.

19. The substrate processing method of claim 15, further comprising:
cleaning, during the developing or following the developing, a peripheral portion of the substrate by using a polar cleaning material.

20. A substrate processing apparatus configured to process a substrate, comprising:
a developing device configured to develop the substrate, using a polar developing material and a non-polar developing material; and
a controller having a processor and a memory with a computer readable program stored therein that upon execution of the computer readable program by the processor configures the controller to:
control the substrate processing apparatus to develop the substrate on which a film of a negative type metal-containing resist is formed and on which an exposure processing and a heating processing after the exposure processing are performed, using the polar developing material and the non-polar developing material.
